(19) United States
(12) Patent Application Publication
(10) Pub. No.: US 2024/0400942 A1
(43) Pub. Date: Dec. 5, 2024

(54) CLEANING COMPOSITION AND CLEANING METHOD OF SEMICONDUCTOR SUBSTRATE

(71) Applicant: FUJIFILM Corporation, Tokyo (JP)

(72) Inventor: Tetsuya KAMIMURA, Shizuoka (JP)

(73) Assignee: FUJIFILM Corporation, Tokyo (JP)

(21) Appl. No.: 18/799,123

(22) Filed: Aug. 9, 2024

Related U.S. Application Data
(63) Continuation of application No. PCT/JP2023/009216, filed on Mar. 10, 2023.

(30) Foreign Application Priority Data
Mar. 17, 2022 (JP) 2022-042280

(51) Int. Cl. C11D 3/30; C11D 3/00; C11D 3/43

(52) U.S. Cl. CPC C11D 3/30; C11D 3/0073; C11D 3/43; C11D 2111/22

(57) ABSTRACT

An object of the present invention is to provide a cleaning composition and a cleaning method of a semiconductor substrate, in which suppression property of surface roughness of a metal part in a substrate is excellent, removability of organic residues is excellent, and removability of inorganic residues is excellent. The cleaning composition of the present invention is a cleaning composition used for cleaning a substrate which has been subjected to a chemical mechanical polishing treatment, the cleaning composition containing an amine compound, an anticorrosion agent, an organic solvent, and water, in which the amine compound includes at least one compound X selected from the group consisting of a tertiary amine compound in which a pKa of a conjugate acid is 8.0 or more and a quaternary ammonium salt compound containing a quaternary ammonium cation having a total number of carbon atoms of 5 or more.

### CROSS-REFERENCE TO RELATED APPLICATIONS

This application is a Continuation of PCT International Application No. PCT/JP2023/009216 filed on Mar. 10, 2023, which claims priority under 35 U.S.C. § 119 (a) to Japanese Patent Application No. 2022-042280 filed on Mar. 17, 2022. The above applications are hereby expressly incorporated by reference, in their entirety, into the present application.

### BACKGROUND OF THE INVENTION

### 1. Field of the Invention

The present invention relates to a cleaning composition and a cleaning method of a semiconductor substrate.

### 2. Description of the Related Art

Semiconductor elements such as a charge-coupled device (CCD) and a memory are manufactured by forming a fine electronic circuit pattern on a substrate using a photolithographic technique. Specifically, the semiconductor elements are manufactured by forming a resist film on a laminate which has a metal film serving as a wiring line material, an etching stop layer, and an interlayer insulating layer on a substrate, and carrying out a photolithography step and a dry etching step (for example, a plasma etching treatment).

In the manufacture of the semiconductor element, a chemical mechanical polishing (CMP) treatment in which a surface of a semiconductor substrate having a metal wiring line film, a barrier metal, an insulating film, or the like is flattened using a polishing slurry containing polishing fine particles (for example, silica and alumina) or the like may be carried out. In the CMP treatment, residues of metal components derived from the polishing fine particles used in the CMP treatment, a polished wiring line metal film, and/or a barrier metal, and the like are likely to remain on the surface of the semiconductor substrate after the CMP treatment.

Since these residues can short-circuit wiring lines and adversely affect electrical characteristics of a semiconductor, a cleaning step in which these residues are removed from the surface of the semiconductor substrate is generally carried out.

For example, JP2019-218548A discloses a composition for cleaning and removing residues and/or contaminants from a microelectronics device containing a specific component.

### SUMMARY OF THE INVENTION

The present inventors have found that, in a case where a substrate which has been subjected to the CMP treatment is cleaned using the cleaning composition disclosed in JP2019-218548A and the like, it is difficult to achieve all of excellent suppression property of surface roughness of a metal part in the substrate, excellent removability of organic residues, and excellent removability of inorganic residues.

An object of the present invention is to provide a cleaning composition and a cleaning method of a semiconductor substrate, in which suppression property of surface roughness of a metal part in a substrate is excellent, removability of organic residues is excellent, and removability of inorganic residues is excellent.

The present inventor has found that the above-described objects can be achieved by the following configurations.

[1]

A cleaning composition used for cleaning a substrate which has been subjected to a chemical mechanical polishing treatment, the cleaning composition comprising:
an amine compound;
an anticorrosion agent;
an organic solvent; and
water,
in which the amine compound includes at least one compound X selected from the group consisting of a tertiary amine compound in which a pKa of a conjugate acid is 8.0 or more and a quaternary ammonium salt compound containing a quaternary ammonium cation having a total number of carbon atoms of 5 or more.

[2]

The cleaning composition according to [1],
in which the amine compound includes at least one selected from the group consisting of the tertiary amine compound in which a pKa of a conjugate acid is 8.0 or more and a compound represented by Formula (B) described later.

[3]

The cleaning composition according to [1] or [2],
in which the tertiary amine compound in which a pKa of a conjugate acid is 8.0 or more includes at least one selected from the group consisting of a tertiary amino alcohol in which a pKa of a conjugate acid is 8.0 or more and a compound represented by Formula (C) described later, in which a pKa of a conjugate acid is 8.0 or more.

[4]

The cleaning composition according to any one of [1] to [3],
in which the cleaning composition contains two or more kinds of the amine compounds.

[5]

The cleaning composition according to any one of [1] to [4],
in which the anticorrosion agent is a heterocyclic compound.

[6]

The cleaning composition according to [5],
in which the anticorrosion agent includes at least one selected from the group consisting of a triazole compound, a tetrazole compound, an imidazole compound, a pyrazole compound, and a purine compound.

[7]

The cleaning composition according to any one of [1] to [6],
in which, in a ternary diagram in which a contribution rate of a dispersion element, a contribution rate of a polarization element, and a contribution rate of a hydrogen bond element in a Hansen solubility parameter of the organic solvent are each represented by a vertex, the organic solvent is located in a region surrounded by a first point to a fourth point,
first point: the contribution rate of the dispersion element is 30%, the contribution rate of the polarization element is 0%, and the contribution rate of the hydrogen bond element is 70%,
second point: the contribution rate of the dispersion element is 30%, the contribution rate of the polarization element is 70%, and the contribution rate of the hydrogen bond element is 0%,
third point: the contribution rate of the dispersion element is 60%, the contribution rate of the polarization element is 40%, and the contribution rate of the hydrogen bond element is 0%, and
fourth point: the contribution rate of the dispersion element is 60%, the contribution rate of the polarization element is 0%, and the contribution rate of the hydrogen bond element is 40%.

[8]

The cleaning composition according to any one of [1] to [7],
in which the organic solvent includes at least one selected from the group consisting of ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate.

[9]

The cleaning composition according to [1] to [8],
in which a mass ratio of a content of the compound X to a content of the organic solvent is 0.01 to 1.

[10]

The cleaning composition according to any one of [1] to [9],
in which a mass ratio of a content of the anticorrosion agent to a content of the organic solvent is 0.001 to 0.5.

[11]

The cleaning composition according to any one of [1] to [10], further comprising:
an organic acid.

[12]

The cleaning composition according to [11],
in which a mass ratio of a content of the organic acid to a content of the organic solvent is 0.01 to 1.

[13]

The cleaning composition according to any one of [1] to [12],
in which the cleaning composition is used for cleaning a semiconductor substrate having copper, cobalt, or tungsten, which has been subjected to a chemical mechanical polishing treatment.

[14]

A cleaning method of a semiconductor substrate, comprising:
a cleaning step of cleaning a semiconductor substrate which has been subjected to a chemical mechanical polishing treatment, using the cleaning composition according to any one of [1] to [13].

According to the present invention, it is possible to provide a cleaning composition and a cleaning method of a semiconductor substrate, in which suppression property of surface roughness of a metal part in a substrate is excellent, removability of organic residues is excellent, and removability of inorganic residues is excellent.

### DESCRIPTION OF THE PREFERRED EMBODIMENTS

Hereinafter, an example of forms for carrying out the present invention will be described in detail.

In the present specification, numerical ranges represented by “to” include numerical values before and after “to” as lower limit values and upper limit values.

In the present specification, in a case where there are two or more components corresponding to a certain component, “content” of such a component means the total content of the two or more components.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, “psi” means pound-force per square inch, where 1 psi=6,894.76 Pa.

In the present specification, “ppm” means “parts-per-million (106)”, and “ppb” means “parts-per-billion (10-9)”.

In the present specification, unless otherwise specified, a weight-average molecular weight (Mw) and a number-average molecular weight (Mn) are values converted using polystyrene as a standard substance, which are measured by a gel permeation chromatography (GPC) analyzer using TSKgel GMHxL, TSKgel G4000HxL, or TSKgel G2000HxL (all of which are manufactured by Tosoh Corporation) as a column, using tetrahydrofuran as an eluent, using a differential refractometer as a detector, and using polystyrene as a standard substance.

In the present specification, unless otherwise specified, a molecular weight of a compound having a molecular weight distribution is the weight-average molecular weight.

In the present specification, “boiling point” means a boiling point at a standard atmospheric present.

### [Cleaning Composition]

The cleaning composition according to the embodiment of the present invention (hereinafter, also referred to as “cleaning composition”) is a cleaning composition used for cleaning a substrate which has been subjected to a chemical mechanical polishing treatment, the cleaning composition containing an amine compound, an anticorrosion agent, an organic solvent, and water, in which the amine compound includes at least one compound X selected from the group consisting of a tertiary amine compound in which a pKa of a conjugate acid is 8.0 or more (hereinafter, also referred to as “specific tertiary amine compound”) and a quaternary ammonium salt compound containing a quaternary ammonium cation having a total number of carbon atoms of 5 or more (hereinafter, also referred to as “specific quaternary ammonium salt compound”).

The mechanism by which the object of the present invention is achieved by the above-described configuration is not clear, but it is presumed that the various components described above act in a cooperative manner to obtain a desired effect.

Hereinafter, the fact that at least one effect of suppression property of surface roughness of a metal part in a substrate, the removability of organic residues, or removability of inorganic residues is more excellent is also referred to as “effect of the present invention is more excellent”.

Hereinafter, various components which can be contained in the cleaning composition will be described in detail.

### [Amine Compound]

The cleaning composition contains an amine compound.

The amine compound includes a compound X described later. In addition, in a case where the amine compound contains the compound X, the amine compound may further contain an amine compound other than the compound X (hereinafter, also referred to as “compound Y”).

The amine compound preferably includes at least one selected from the group consisting of the specific tertiary amine compound and a compound represented by Formula (B), and more preferably includes at least one selected from the group consisting of a compound represented by Formula (C) in which a pKa of a conjugate acid is 8.0 or more and a compound represented by Formula (B).

### <Compound X>

The compound X is at least one compound selected from the group consisting of the specific tertiary amine compound and the specific quaternary ammonium salt compound.

### (Specific Tertiary Amine Compound)

The specific tertiary amine compound is a tertiary amine compound in which a pKa of a conjugate acid is 8.0 or more.

The pKa of the conjugate acid of the above-described tertiary amine compound is 8.0 or more, preferably 9.0 or more and more preferably 10.0 or more. The upper limit thereof may be 14.0 or less, preferably 13.5 or less.

In a case where one kind of tertiary amine compound has pKa's of a plurality of conjugate acids, it is sufficient that the highest pKa of the plurality of conjugate acids is 8.0 or more. Specifically, in a case where one kind of tertiary amine compound has pKa's of three conjugate acids, which are a first pKa: 1, a second pKa: 4, and a third pKa: 10, the highest third pKa is 10 and is 8.0 or more, and thus the one kind of tertiary amine compound corresponds to the specific tertiary amine compound.

As the pKa of the conjugate acid described above, for example, a value in water (temperature: 25° C.) calculated using Calculator Plugins (manufactured by Fujitsu Ltd.) can be used. In a case where the measurement cannot be performed in water, a value calculated in dimethyl sulfoxide can be used.

The specific tertiary amine compound has a tertiary amino group.

In addition, the tertiary amino group included in the specific tertiary amine compound may be a ring member atom.

The number of tertiary amino groups included in the specific tertiary amine compound is 1 or more, preferably 1 to 5 and more preferably 1 to 3.

The specific tertiary amine compound may have a group other than the tertiary amino group.

Examples of other groups include an alkyl group, a hydroxy group, a primary amino group, a secondary amino group, a heterocyclic group having a nitrogen atom as a ring member atom, and a group formed by a combination of these groups.

As the heterocyclic group having a nitrogen atom as a ring member atom, for example, an aliphatic heterocyclic group having a nitrogen atom as a ring member atom or an aromatic heterocyclic group having a nitrogen atom as a ring member atom may be used. Examples of the heterocyclic group having a nitrogen atom as a ring member atom include aliphatic heterocyclic groups such as a pyrrolidine ring group and a piperidine ring group; and aromatic heterocyclic groups such as a pyridine ring group, an imidazole ring group, and an indole ring group.

It is preferable that the specific tertiary amine compound preferably has the tertiary amino group and further has at least one kind selected from the group consisting of the primary amino group, the secondary amino group, the tertiary amino group, the heterocyclic group having a nitrogen atom as a ring member atom, and a group formed by a combination of these groups. In addition, it is also preferable that the specific tertiary amine compound has the tertiary amino group and does not have the primary amino group or the secondary amino group.

The specific tertiary amine compound preferably includes at least one selected from the group consisting of a tertiary amino alcohol in which a pKa of a conjugate acid is 8.0 or more and a compound represented by Formula (C) in which a pKa of a conjugate acid is 8.0 or more.

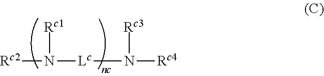

In Formula (C), R^{c1} to R^{c4} each independently represent an alkyl group, L^{c} represents an alkylene group, and nc represents an integer of 1 to 3.

In Formula (C), R^{c1} to R^{c4} each independently represent an alkyl group.

The above-described alkyl group may be linear, branched, or cyclic, and is preferably linear.

The number of carbon atoms in the above-described alkyl group is preferably 1 to 30, more preferably 1 to 15, still more preferably 1 to 5, and particularly preferably 1 to 3.

Examples of the above-described alkyl group include a methyl group, an ethyl group, a propyl group, and a butyl group, and a methyl group or an ethyl group is preferable.

In Formula (C), L^{c} represents an alkylene group.

The above-described alkylene group may be linear, branched, or cyclic, and is preferably linear.

The number of carbon atoms in the above-described alkylene group is preferably 1 to 30, more preferably 1 to 15, still more preferably 1 to 5, and particularly preferably 1 to 3.

Examples of the above-described alkylene group include a methylene group, an ethylene group, a propylene group, and a butylene group, and an ethylene group or a propylene group is preferable.

In Formula (C), nc represents an integer of 1 to 3.

In a case of a plurality of R^{c1}'s, R^{c1}'s may be the same or different from each other. In a case of a plurality of L^{c}'s, L^{c}'s may be the same or different from each other.

Examples of the tertiary amino alcohol in which a pKa of a conjugate acid is 8.0 or more include 2-dimethylamino-2-methyl-1-propanol, methyldiethanolamine, butyldiethanolamine, ethyldiethanolamine, propyldiethanolamine, 2-[[2-(dimethylamino)ethyl]methylamino]ethanol, bis(2-hydroxyethyl)aminotris(hydroxymethyl)methane (Bis-Tris-Propane), 2-(dimethylamino)ethanol (DMAE), N-ethyldiethanolamine (EDEA), 2-diethylaminoethanol, 2-(dibutylamino)ethanol, 2-[2-(dimethylamino)ethoxy]ethanol, 2-[2-(diethylamino)ethoxy]ethanol, N-butyldiethanolamine (BDEA), N-tert-butyldiethanolamine (t-BDEA), 1-[bis(2-hydroxyethyl)amino]-2-propanol (Bis-HEAP), 1-(2-hydroxyethyl)piperazine (HEP), 1,4-bis(2-hydroxyethyl)piperazine (BHEP), 2-(N-ethylanilino)ethanol, N-phenyldiethanolamine (Ph-DEA), N-benzyldiethanolamine, 2-(dimethylamino)-1,3-propanediol, 2-[[2-(dimethylamino)ethyl]methylamino]ethanol, stearyldiethanolamine, and derivatives thereof.

Examples of the compound represented by Formula (C) in which a pKa of a conjugate acid is 8.0 or more include tetramethylethylenediamine, N,N,N′,N′-tetramethyl-1,3-propanediamine, N,N,N′,N″,N″-pentamethyldiethylenetriamine, and 1,3-bis(dimethylamino) butane.

Examples of the specific tertiary amine compound also include trimethylamine and triethylamine.

The specific tertiary amine compound preferably includes at least one selected from the group consisting of 2-dimethylamino-2-methyl-1-propanol, N,N,N′,N′-tetramethylethylenediamine, N,N,N′,N′-tetramethyl-1,3-propanediamine, N,N,N′,N″,N″-pentamethyldiethylenetriamine, and methyldiethanolamine; and more preferably includes least one selected from the group consisting of 2-dimethylamino-2-methyl-1-propanol, N,N,N′,N′-tetramethylethylenediamine, N,N,N′,N′-tetramethyl-1,3-propanediamine, N,N,N′,N″,N″-pentamethyldiethylenetriamine, and methyldiethanolamine.

### (Specific Quaternary Ammonium Salt Compound)

The specific quaternary ammonium salt compound is a quaternary ammonium salt compound containing a quaternary ammonium cation having the total number of carbon atoms of 5 or more.

The above-described total number of carbon atoms represents the total number of carbon atoms in the quaternary ammonium cation contained in the specific quaternary ammonium compound. As will be described later, the specific quaternary ammonium salt compound contains an anion in addition to the above-described cation. That is, the number of carbon atoms in the anion contained in the quaternary ammonium salt compound is not included in the above-described total number of carbon atoms.

The total number of carbon atoms in the quaternary ammonium cation contained in the specific quaternary ammonium salt compound is 5 or more, preferably 6 or more and more preferably 7 or more. The upper limit thereof is preferably 20 or less and more preferably 16 or less.

The specific quaternary ammonium salt compound is a compound containing the above-described quaternary ammonium cation having the total number of carbon atoms of 5 or more and an anion.

The specific quaternary ammonium salt compound may have two or more of the above-described quaternary ammonium cations having the total number of carbon atoms of 5 or more, and may have two or more anions.

The specific quaternary ammonium salt compound may further contain other cations as long as the specific quaternary ammonium salt compound contains the above-described quaternary ammonium cation having the total number of carbon atoms of 5 or more. Examples of the above-described other cations include a phosphonium cation.

The above-described anion may be any of a monovalent anion or a di or higher-valent anion.

Examples of the above-described anion include an organic anion and an inorganic anion. Specific examples thereof include an acid anion such as a carboxylate ion, a phosphate ion, a sulfate ion, a phosphonate ion, and a nitrate ion; a hydroxide ion; and a halide ion such as a chloride ion, a fluoride ion, and a bromide ion, and a hydroxide ion is preferable.

The quaternary ammonium cation having the total number of carbon atoms of 5 or more is a cation including a nitrogen atom to which four substituents are bonded.

Examples of the above-described substituent include a halogen atom such as a fluorine atom, a chlorine atom, and a bromine atom, a hydroxy group, an organic group, and a group formed by a combination of these groups.

As the above-described substituent, a hydrocarbon group which may have a substituent or may have —O— is preferable.

The number of carbon atoms in the above-described hydrocarbon group is preferably 1 to 30, more preferably 1 to 10, and still more preferably 1 to 5.

Examples of the above-described hydrocarbon group include an alkyl group which may have a substituent or may have —O—, an alkenyl group which may have a substituent or may have —O—, an alkynyl group which may have a substituent or may have —O—, an aryl group which may have a substituent or may have —O—, and a group obtained by combining these groups, and an alkyl group which may have a substituent or may have —O— is preferable.

Examples of the substituent included in the above-described hydrocarbon group include a halogen atom such as a fluorine atom, a chlorine atom, and a bromine atom; an alkoxy group; a hydroxy group; an alkoxycarbonyl group such as a methoxycarbonyl group and an ethoxycarbonyl group; an acyl group such as an acetyl group, a propionyl group, and benzoyl group; a cyano group; and a nitro group, and a hydroxy group is preferable. In addition, the substituent included in the above-described hydrocarbon group may be a group having a quaternary ammonium cation.

It is also preferable that the above-described hydrocarbon group is unsubstituted.

The alkyl group, the alkenyl group, and the alkynyl group described above may be linear, branched, or cyclic.

The number of carbon atoms in the alkyl group, the alkenyl group, and the alkynyl group described above is preferably 1 to 30, more preferably 1 to 10, still more preferably 1 to 5, and particularly preferably 1 to 3.

As the above-described alkyl group, an unsubstituted alkyl group or an alkyl group which has a hydroxy group and may have —O— is preferable, and an unsubstituted alkyl group or an alkyl group which has a hydroxy group is more preferable.

The unsubstituted alkyl group is an alkyl group having neither a substituent nor —O— (for example, a methyl group, an ethyl group, and the like).

The above-described aryl group may be monocyclic or polycyclic.

The number of carbon atoms in the above-described aryl group is preferably 6 to 20, more preferably 6 to 10, and still more preferably 6 to 8.

As the above-described aryl group, an unsubstituted aryl group (aryl group which does not have a substituent and —O—) or an aryl group having a hydroxy group is preferable, and an unsubstituted aryl group is more preferable.

The unsubstituted aryl group is an aryl group which does not have a substituent and —O— (for example, a phenyl group and a naphthyl group).

Examples of the above-described aryl group include a benzyl group, a phenyl group, a naphthyl group, an anthryl group, a phenanthryl group, an indenyl group, an acenabutenyl group, a fluorenyl group, and a pyrenyl group, and a phenyl group is preferable.

It is preferable that the four substituents of the nitrogen atom constituting the above-described quaternary ammonium cation represent at least two or more kinds of groups.

In addition, it is preferable that at least two of the four substituents of the nitrogen atom constituting the above-described quaternary ammonium cation represent the same group.

From the viewpoint that the effect of the present invention is more excellent, the specific quaternary ammonium salt compound is preferably a compound represented by Formula (B).

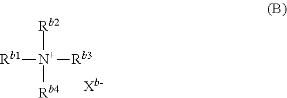

In Formula (B), R^{b1} to R^{b4} each independently represent an alkyl group which may have a substituent and may have —O—, X^{b-} represents an anion, here, a case where all of R^{b1} to R^{b4} represent the same group is excluded, and the total number of carbon atoms in R^{b1} to R^{b4} is 5 or more.

In Formula (B), R^{b1} to R^{b4} each independently represent an alkyl group which may have a substituent and may have —O—.

The above-described alkyl group may be linear, branched, or cyclic.

The number of carbon atoms in the above-described alkyl group is preferably 1 to 20, more preferably 1 to 10, still more preferably 1 to 5, and particularly preferably 1 to 3.

Examples of the above-described substituent include a hydroxy group, a carboxy group, and a halogen atom (for example, a fluorine atom, a chlorine atom, and a bromine atom), and a hydroxy group is preferable.

As R^{b1} to R^{b4}, an alkyl group which may have a hydroxy group is preferable.

Examples of the alkyl group having —O— include an alkyl group in which a methylene group is replaced with —O—.

X^{b-} represents an anion.

Examples of the above-described anion include the anion contained in the specific quaternary ammonium salt compound described above, and a hydroxide ion is preferable.

Here, a case where all of R^{b1} to R^{b4} represent the same group is excluded.

For example, in a case where all of R^{b1} to R^{b4} represent a methyl group, because R^{b1} to R^{b4} are the same group, the requirement of “a case where all of R^{b1} to R^{b4} represent the same group is excluded” is not satisfied. On the other hand, in a case where all of R^{b1} to R^{b3} are methyl groups and R^{b4} is an ethyl group, because not all of R^{b1} to R^{b4} are the same group, the requirement of “a case where all of R^{b1} to R^{b4} represent the same group is excluded” is satisfied. In a case where at least one of the type of the substituent or the type of the alkyl group is different, the groups are not the same. That is, in a case where two groups are compared, the two groups are different groups in a case where at least one of the type of the substituent or the type of the alkyl group is different. For example, because there is a difference in overall structure between an ethyl group and a hydroxyethyl group, these groups are not the same group.

In other words, the “a case where all of R^{b1} to R^{b4} represent the same group is excluded” means that four groups represented by R^{b1} to R^{b4} represent at least two kinds of groups. For example, in the case where all of R^{b1} to R^{b3} are methyl groups and R^{b4} is an ethyl group, four groups represented by R^{b1} to R^{b4} represent two types of groups, a methyl group and an ethyl group.

Examples of an aspect of R^{b1} to R^{b4} include an aspect in which, in four groups represented by R^{b1} to R^{b4}, three groups represented by R^{b1} to R^{b3} are the same group and one group represented by R^{b4} is a group different from the three groups. Examples thereof also include an aspect in which, in four groups represented by R^{b1} to R^{b4}, two groups represented by R^{b1} and R^{b2} are the same group, two groups represented by R^{b3} and R^{b4} are the same group, and the group represented by R^{b1} and R^{b2} is different from the group represented by R^{b3} and R^{b4}. In addition, all of four groups represented by R^{b1} to R^{b4} may be different groups.

The total number of carbon atoms in R^{b1} to R^{b4} is 5 or more, preferably 5 to 24, more preferably 6 to 20, and still more preferably 7 to 16.

The total number of carbon atoms in R^{b1} to R^{b4} means the total number of carbon atoms included in each group represented by any of R^{b1} to R^{b4}.

Examples of the specific quaternary ammonium salt compound include cthyltrimethylammonium hydroxide, tetraethylammonium hydroxide, tetrapropylammonium hydroxide, tetrabutylammonium hydroxide, 2-hydroxyethyltrimethylammonium hydroxide, tris(2-hydroxyethyl)methylammonium hydroxide, dimethyldioctadecylammonium chloride, N,N′-ethylenebis(trimethylammonium), dimethylbis(2-hydroxyethyl) ammonium hydroxide, decamethonium bromide, 1,3-dihydroxypropyltrimethylammonium hydroxide, and N¹-(1-hydroxy-2-methylpropan-2-yl)-N²-(2-hydroxypropyl)-N¹,N¹,N²,N^{2,2}-pentamethylpropan-1,2-diaminium dihydroxide.

The specific quaternary ammonium salt compound preferably includes at least one selected from the group consisting of tris(2-hydroxyethyl)methylammonium hydroxide, ethyltrimethylammonium hydroxide, 2-hydroxyethyltrimethylammonium hydroxide, dimethylbis(2-hydroxyethyl) ammonium hydroxide, tetraethylammonium hydroxide, and tetrabutylammonium hydroxide; and more preferably includes at least one selected from the group consisting of tris(2-hydroxyethyl)methylammonium hydroxide, ethyltrimethylammonium hydroxide, 2-hydroxyethyltrimethylammonium hydroxide, and dimethylbis(2-hydroxyethyl) ammonium hydroxide.

An anion in the exemplary compounds of the specific quaternary ammonium salt compound described above may be an anion other than those described above. The above-described anion is as described above. For example, ethyltrimethylammonium hydroxide may be either ethyltrimethylammonium chloride or ethyltrimethylammonium fluoride.

In addition, examples of the specific quaternary ammonium salt compound also include compounds described in WO2020/214692A, the content of which is incorporated herein by reference.

A content of the compound X is preferably 0.01% to 15% by mass, more preferably 0.03% to 8% by mass, and still more preferably 0.05% to 5% by mass with respect to the total mass of the cleaning composition.

### <Compound Y>

The compound Y is an amine compound other than the compound X.

The compound Y is preferably an amine compound having no aromatic ring.

Examples of the compound Y include a primary aliphatic amine compound, a secondary aliphatic amine compound, a tertiary aliphatic amine compound in which a pKa of a conjugate acid is less than 8.0, a primary amino alcohol, a secondary amino alcohol, and a tertiary amino alcohol in which a pKa of a conjugate acid is less than 8.0. Among these, a primary aliphatic amine compound, a secondary aliphatic amine compound, a primary amino alcohol, a secondary amino alcohol, or a tertiary amino alcohol in which a pKa of a conjugate acid is less than 8.0 is preferable; and a primary amino alcohol, a secondary amino alcohol, or a tertiary amino alcohol in which a pKa of a conjugate acid is less than 8.0 is more preferable.

In a case where the compound Y has amino groups of different order, the compound Y is classified into an amine compound having the highest order of amino group among the amino groups.

The pKa of the conjugate acid of the above-described tertiary aliphatic amine compound and the above-described tertiary amino alcohol is less than 8.0, preferably 7.8 or less. The lower limit thereof may be −2.0 or more.

The above-described pKa of the conjugate acid can be measured by the same method as that for the specific tertiary amine compound.

Examples of the primary aliphatic amine compound include methylamine, ethylamine, propylamine, dimethylamine, diethylamine, n-butylamine, 3-methoxypropylamine, tert-butylamine, n-hexylamine, n-octylamine, 2-ethylhexylamine, cyclohexylamine, and derivatives thereof; and ethylamine or a derivative thereof is preferable.

Examples of the secondary aliphatic amine compound include propylene diamines such as ethylenediamine (EDA), 1,3-propanediamine (PDA), and 1,2-propanediamine; alkylenediamines such as 1,3-butanediamine and 1,4-butanediamine; secondary polyalkylpolyamines such as diethylenetriamine (DETA), triethylenetetramine (TETA), bis(aminopropyl)ethylenediamine (BAPEDA), and tetraethylenepentamine; piperazine, 2-methylpiperazine, 2,5-dimethylpiperazine, and 2,6-dimethylpiperazine; and derivatives thereof. Among these, propylenediamine, triethylenetetramine, or a derivative thereof is preferable.

The tertiary aliphatic amine compound in which a pKa of a conjugate acid is less than 8.0 is a tertiary amine having a tertiary amino group and not having an aromatic ring group.

Examples of the above-described tertiary aliphatic amine compound include tertiary polyalkylpolyamine in which a pKa of a conjugate acid is less than 8.0; a tertiary cyclic amidine compound in which a pKa of a conjugate acid is less than 8.0; a tertiary piperazine compound in which a pKa of a conjugate acid is less than 8.0; a tertiary oxazolidone compound in which a pKa of a conjugate acid is less than 8.0 (for example, 3-methyl-2-oxazolidone and the like); a tertiary imidazolidinone compound in which a pKa of a conjugate acid is less than 8.0 (for example, 1,3-dimethyl-2-imidazolidinone and the like); and derivatives thereof.

Examples of the primary amino alcohol include tris(hydroxymethyl)aminomethane (Tris), monoethanolamine (MEA), 2-amino-1,3-propanediol, 3-amino-1,2-propanediol, 1,3-diamino-2-propanol, 2-amino-2-methyl-1-propanol (AMP), 3-amino-1-propanol, 1-amino-2-propanol, diethylene glycolamine (DEGA), 2-(aminoethoxy)ethanol (AEE), and derivatives thereof. Among these, AMP, AEE, or a derivative thereof is preferable, and AEE or a derivative thereof is more preferable.

Examples of the secondary amino alcohol include 1,3-bis[tris(hydroxymethyl)methylamino]propane, uracil, N-methylethanolamine, 2-(ethylamino)ethanol, 2-[(hydroxymethyl)amino]ethanol, 2-(propylamino)ethanol, N,N′-bis(2-hydroxyethyl)ethylenediamine, diethanolamine, 2-(2-aminoethylamino)ethanol (AAE), N-butylethanolamine, N-cyclohexylethanolamine, and derivatives thereof.

Examples of the tertiary amino alcohol in which a pKa of a conjugate acid is less than 8.0 include triethanolamine, p-triethanolamine, and m-triethanolamine.

Examples of the compound Y also include a quaternary ammonium salt compound containing a quaternary ammonium cation having the total number of carbon atoms of less than 5 (a quaternary ammonium salt compound other than the specific quaternary ammonium salt compound).

A content of the compound Y is preferably 0.01% to 10% by mass, more preferably 0.03% to 10% by mass, still more preferably 0.03% to 8% by mass, and particularly preferably 0.05% to 5% by mass with respect to the total mass of the cleaning composition.

The amine compound may be used alone or in combination of two or more kinds thereof, and it is preferable to be used in combination of two or more kinds thereof and more preferable to be used in combination of two kinds thereof.

The use of two or more kinds of amine compounds described above means that at least one of the two or more kinds of amine compounds is the compound X, and the remaining is any of the compound X or the compound Y.

A content of the amine compound is preferably 0.02% to 20% by mass, more preferably 0.05% to 10% by mass, and still more preferably 0.1% to 10% by mass with respect to the total mass of the cleaning composition.

### [Anticorrosion Agent]

The cleaning composition contains an anticorrosion agent.

The anticorrosion agent is a compound different from the various components described above.

Examples of the anticorrosion agent include compounds having a heteroatom, and a compound having a heterocycle (a heterocyclic compound) is preferable, and a compound having a polycyclic heterocycle is more preferable.

Examples of the anticorrosion agent include a purine compound, an azole compound, and a reducing sulfur compound.

The anticorrosion agent preferably includes at least one selected from the group consisting of a triazole compound, a tetrazole compound, an imidazole compound, a pyrazole compound, and a purine compound; and more preferably includes a purine compound.

In addition, it is also preferable that the anticorrosion agent does not have a sulfur atom.

### <Purine Compound>

The purine compound is at least one compound selected from the group consisting of purine and a purine derivative.

Examples of the purine compound include adenine, guanine, kinetin, purine, hypoxanthine, xanthine, theobromine, caffeine, uric acid, isoguanine, adenosine, enprofylline, theophylline, xanthosine, 7-methylxanthosine, 7-methylxanthine, eritadenine, 3-methyladenine, 3-methylxanthine, 1,7-dimethylxanthine, 1-methylxanthine, paraxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl) xanthine, 1-butyl-3,7-dimethylxanthine, 3,7-dimethyl-1-propylxanthine, mercaptopurine, 2-aminopurine, 6-aminopurine, 6-benzylaminopurine, nelarabine, vidarabine, 2,6-dichloropurine, aciclovir, N⁶-benzoyladenosine, trans-zeatin, 6-benzylaminopurine, entecavir, valaciclovir, abacavir, 2′-deoxyguanosine, disodium inosinate, ganciclovir, guanosine 5′-disodium monophosphate, O-cyclohexylmethylguanine, N²-isobutyryl-2′-deoxyguanosine, β-nicotinamide adenine dinucleotide phosphate, 6-chloro-9-(tetrahydropyran-2-yl) purine, clofarabine, 7-(2,3-dihydroxypropyl) theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl) adenine, 7-(2-chloroethyl) theophylline, 2-amino-6-iodopurine, 2-thioxanthine, 2-amino-6-methoxypurine, N-acetylguanine, adefovir dipivoxil, 8-chlorotheophylline, 6-methoxypurine, 1-(3-chloropropyl) theobromine, 6-(dimethylamino) purine, and inosine, and derivatives thereof.

As the purine compound, adenosine, guanine, adenine, kinetin, or a derivative thereof is preferable.

### <Azole Compound>

The azole compound is a compound having an aromatic heterocyclic 5-membered ring including a nitrogen atom.

The number of nitrogen atoms included in the aromatic heterocyclic 5-membered ring of the azole compound is preferably 1 to 4 and more preferably 1 to 3.

The azole compound may have a substituent on the aromatic heterocyclic 5-membered ring. Examples of the substituent include a hydroxy group, a carboxy group, a mercapto group, an amino group, an alkyl group having 1 to 4 carbon atoms, which may have an amino group, and a 2-imidazolyl group.

Examples of the azole compound include an imidazole compound in which one of the atoms constituting an azole ring is a nitrogen atom, a pyrazole compound in which two of the atoms constituting an azole ring are nitrogen atoms, a thiazole compound in which one of the atoms constituting an azole ring is a nitrogen atom and the other is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, benzimidazole, and derivatives thereof; and benzimidazole is preferable.

Examples of the pyrazole compound include 2,4-dimethylthiazole, 3,5-dimethylpyrazole, benzothiazole, 2-mercaptobenzothiazole, and derivatives thereof; and 3,5-dimethylpyrazole is preferable.

Examples of the thiazole compound include 2,4-dimethylthiazole, benzothiazole, 2-mercaptobenzothiazole, and derivatives thereof.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol, and derivatives thereof; and 1,2,3-triazole is preferable.

Examples of the tetrazole compound include 1H-tetrazole (1,2,3,4-tetrazole), 5-methyltetrazole, 5-aminotetrazole, 1,5-pentamethylenetetrazole, 1-phenyl-5-mercaptotetrazole, 1-(2-dimethylaminoethyl)-5-mercaptotetrazole, and derivatives thereof; and 5-aminotetrazole is preferable.

As the azole compound, a triazole compound, a tetrazole compound, an imidazole compound, or a pyrazole compound is preferable.

### <Reducing Sulfur Compound>

The reducing sulfur compound is a reducing compound having a sulfur atom.

Examples of the reducing sulfur compound include 3-mercapto-1,2,4-triazole, mercaptosuccinic acid, mercaptopropionic acid, dithiodiglycerol, cysteine, cysteamine, thiourea, bis(2,3-dihydroxypropylthio)ethylene, 3-(2,3-dihydroxypropylthio)-2-methyl-propylsulfonate, 1-thioglycerol, 3-mercapto-1-propanesulfonate, 2-mercaptoethanol, thioglycolic acid, 3-mercapto-1-propanol, and derivatives thereof.

The anticorrosion agent may be used alone or in combination of two or more kinds thereof.

A content of the anticorrosion agent is preferably 0.0001% to 20% by mass, more preferably 0.001% to 10% by mass, and still more preferably 0.005% to 5% by mass with respect to the total mass of the cleaning composition.

### [Organic Solvent]

The cleaning composition contains an organic solvent.

It is preferable that, in a ternary diagram in which a contribution rate of a dispersion element, a contribution rate of a polarization element, and a contribution rate of a hydrogen bond element in a Hansen solubility parameter of the organic solvent are each represented by a vertex, the organic solvent is located in a region surrounded by a first point to a fourth point.
First point: the contribution rate of the dispersion element is 30%, the contribution rate of the polarization element is 0%, and the contribution rate of the hydrogen bond element is 70%
Second point: the contribution rate of the dispersion element is 30%, the contribution rate of the polarization element is 70%, and the contribution rate of the hydrogen bond element is 0%
Third point: the contribution rate of the dispersion element is 60%, the contribution rate of the polarization element is 40%, and the contribution rate of the hydrogen bond element is 0%
Fourth point: the contribution rate of the dispersion element is 60%, the contribution rate of the polarization element is 0%, and the contribution rate of the hydrogen bond element is 40%

In the present specification, the Hansen solubility parameter means a Hansen solubility parameter described in “Hansen Solubility Parameters: A Users Handbook, Second Edition” (pp. 1 to 310, CRC Press, 2007) or the like. That is, the Hansen solubility parameter is represented by a multidimensional vector (dispersion element (8d), polarization element (Sp), and hydrogen bond element (8h)), and the three parameters also mean coordinates of a point in a three-dimensional space called Hansen space. The unit of each element of the Hansen solubility parameter is (MPa) 0.5.

In the present specification, the contribution rate (fd) of the dispersion element, the contribution rate (fp) of the polarization element, and the contribution rate (fh) of the hydrogen bond element in the Hansen solubility parameter can be calculated by any of Expression (f1) to Expression (f3).

$$fd ( \% ) = δ d / ( δ d + δ p + δ h ) \times 100 \qquad Expression ( f1 )$$

$$fp ( \% ) = δ p / ( δ d + δ p + δ h ) \times 100 \qquad Expression ( f2 )$$

$$fh ( \% ) = δ h / ( δ d + δ p + δ h ) \times 100 \qquad Expression ( f3 )$$

In the ternary diagram in which the contribution rate of the dispersion element, the contribution rate of the polarization element, and the contribution rate of the hydrogen bond element in the Hansen solubility parameter of the organic solvent are each represented by a vertex, examples of the organic solvent in the region surrounded by the first point to the fourth point described above include ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate.

Examples of the ethylene glycol alkyl ether including an alkyl ether having an alkyl group having 1 to 6 carbon atoms include ethylene glycol monomethyl ether and ethylene glycol monobutyl ether.

Examples of the diethylene glycol alkyl ether including an alkyl ether having an alkyl group having 1 to 6 carbon atoms include diethylene glycol methyl ether and diethylene glycol ethyl ether.

With regard to the Hansen solubility parameter of the organic solvent, for example, the description in paragraphs [0066] to [0071] of WO2018/151164A can be referred to.

As the organic solvent, a hydrophilic organic solvent is also preferable.

Examples of the hydrophilic organic solvent include a water-soluble alcohol-based solvent, a water-soluble ketone-based solvent, a water-soluble ester-based solvent, a water-soluble ether-based solvent, a sulfone-based solvent, a sulfoxide-based solvent, and a nitrile-based solvent; and an alkanediol, an alkoxy alcohol, a glycol monoether, a water-soluble ketone-based solvent, a water-soluble ester-based solvent, a sulfone-based solvent, or a sulfoxide-based solvent is preferable.

Examples of the water-soluble alcohol-based solvent include alkanediol (for example, alkylene glycol and the like), alkoxy alcohol (for example, glycol monoether and the like), a saturated aliphatic monohydric alcohol, an unsaturated non-aromatic monohydric alcohol, and a low-molecular-weight alcohol including a ring structure.

Examples of the alkanediol include glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, 2-methyl-2,4-pentanediol, pinacol, and alkylene glycol; and 2-methyl-2,4-pentanediol is preferable.

Examples of the alkylene glycol include ethylene glycol, propylene glycol, diethylene glycol, dipropylene glycol, triethylene glycol, and tetraethylene glycol.

Examples of the alkoxy alcohol include 3-methoxy-3-methyl-1-butanol, 3-methoxy-1-butanol, 1-methoxy-2-butanol, and glycol monoether; and 3-methoxy-3-methyl-1-butanol is preferable.

Examples of the glycol monoether include dipropylene glycol butyl ether, ethylene glycol monomethyl ether, ethylene glycol monoethyl ether, ethylene glycol monobutyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, 1-butoxy-2-propanol, 2-isobutoxyethanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether. Among these, 1-butoxy-2-propanol, 2-isobutoxyethanol, ethylene glycol monomethyl ether, or ethylene glycol monobutyl ether is preferable.

Examples of the saturated aliphatic monohydric alcohol include methanol, ethanol, n-propyl alcohol, isopropyl alcohol, 1-butanol, 2-butanol, isobutyl alcohol, tert-butyl alcohol, 2-pentanol, t-pentyl alcohol, and 1-hexanol.

Examples of the unsaturated non-aromatic monohydric alcohol include allyl alcohol, propargyl alcohol, 2-butenyl alcohol, 3-butenyl alcohol, and 4-penten-2-ol.

Examples of the low-molecular-weight alcohol including a ring structure include tetrahydrofurfuryl alcohol, furfuryl alcohol, and 1,3-cyclopentanediol.

Examples of the water-soluble ketone-based solvent include propylene carbonate, acetone, propanone, cyclobutanone, cyclopentanone, cyclohexanone, diacetone alcohol, 2-butanone, 5-hexanedione, 1,4-cyclohexanedione, 3-hydroxyacetophenone, 1,3-cyclohexanedione, and cyclohexanone; and propylene carbonate or cyclohexanone is preferable.

Examples of the water-soluble ester-based solvent include ethyl acetate; glycol monoesters such as ethylene glycol monoacetate and diethylene glycol monoacetate; and glycol monoether monoesters such as propylene glycol monomethyl ether acetate, ethylene glycol monomethyl ether acetate, propylene glycol monoethyl ether acetate, and ethylene glycol monoethyl ether acetate. Among these, glycol monoether monoester is preferable, and ethylene glycol monoethyl ether acetate is more preferable.

Examples of the sulfone-based solvent include sulfolane, 3-methylsulfolane, and 2,4-dimethylsulfolane, and sulfolane is preferable.

Examples of the sulfoxide-based solvent include dimethyl sulfoxide.

Examples of the nitrile-based solvent include acetonitrile.

The organic solvent preferably includes at least one selected from the group consisting of cyclohexanone, ethylene glycol monomethyl ether, ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate; more preferably includes at least one selected from the group consisting of ethylene glycol monomethyl ether, ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate; and still more preferably includes at least one selected from the group consisting of ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, and sulfolane.

A boiling point of the organic solvent is preferably 10° C. to 300° C., more preferably 30° C. to 290° C., and still more preferably 40° C. to 290° C.

A molecular weight of the organic solvent is preferably 30 to 500, more preferably 40 to 450, and still more preferably 60 to 400.

The organic solvent may be used alone or in combination of two or more kinds thereof.

A content of the organic solvent is preferably 1% to 95% by mass, more preferably 3% to 90% by mass, and still more preferably 5% to 85% by mass with respect to the total mass of the cleaning composition.

### [Water]

The cleaning composition contains water.

Examples of the water include distilled water, deionized water, and pure water (ultrapure water). From the viewpoint that influence on a semiconductor substrate in a manufacturing process of the semiconductor substrate is smaller, the above-described water is preferably pure water (ultrapure water).

The content of the water is preferably 1.0% by mass or more, more preferably 30.0% by mass or more, still more preferably 50.0% by mass or more, and particularly preferably 60.0% by mass or more with respect to the total mass of the cleaning composition. The upper limit thereof is preferably 99.99% by mass or less, more preferably 99.9% by mass or less, and still more preferably 99.0% by mass or less with respect to the total mass of the cleaning composition.

### [Organic Acid]

The cleaning composition may contain an organic acid.

The organic acid is a compound different from the various components described above.

Examples of the organic acid include a carboxylic acid-based organic acid such as an aliphatic carboxylic acid-based organic acid and an aromatic carboxylic acid-based organic acid, and a phosphonic acid-based organic acid; and a carboxylic acid-based organic acid is preferable and a dicarboxylic acid is more preferable.

The organic acid may be in a form of a salt. Examples of the above-described salt include a sodium salt and a potassium salt.

The carboxylic acid-based organic acid is a compound having one or two or more carboxy groups.

The carboxylic acid-based organic acid may further have a hydroxy group as a group other than the carboxy group.

The number of carboxy groups included in the carboxylic acid-based organic acid is preferably 1 to 10, more preferably 2 to 10, and still more preferably 3 to 5.

Examples of the aliphatic carboxylic acid-based organic acid include oxalic acid, malonic acid, succinic acid, glutaric acid, adipic acid, pimelic acid, sebacic acid, maleic acid, citric acid, tartaric acid, lactic acid, glycolic acid, and gluconic acid. Among these, succinic acid, oxalic acid, malonic acid, succinic acid, glutaric acid, or adipic acid is preferable, and succinic acid, oxalic acid, malonic acid, glutaric acid, or adipic acid is more preferable.

Examples of the aromatic carboxylic acid-based organic acid include phthalic acid, isophthalic acid, terephthalic acid, gallic acid, trimellitic acid, mellitic acid, and cinnamic acid; and trimellitic acid is preferable.

Examples of the phosphonic acid-based organic acid include compounds described in paragraphs [0026] to [0036] of WO2018/020878A and compounds described in paragraphs [0031] to [0046] of WO2018/030006A, the content of which is incorporated herein by reference.

The organic acid may be used alone or in combination of two or more kinds thereof.

A content of the organic acid is preferably 0.001% to 20% by mass, more preferably 0.01% to 10% by mass, and still more preferably 0.05% to 5% by mass with respect to the total mass of the cleaning composition.

### [Mass Ratio of Contents of Various Components]

A mass ratio of the content of the compound X to the content of the organic solvent (content of compound X/content of organic solvent) is preferably 0.001 to 10, more preferably 0.01 to 1, and still more preferably 0.04 to 1.

A mass ratio of the content of the amine compound other than the compound X (compound Y) to the content of the organic solvent (content of compound Y/content of organic solvent) is preferably 0.002 to 2, more preferably 0.004 to 2, still more preferably 0.004 to 1.5, and particularly preferably 0.006 to 1.

A mass ratio of the content of the anticorrosion agent to the content of the organic solvent (content of anticorrosion agent/content of organic solvent) is preferably 0.0008 to 1.6, more preferably 0.0009 to 1, and still more preferably 0.001 to 0.5.

A mass ratio of the content of the organic acid to the content of the organic solvent (content of organic acid/content of organic solvent) is preferably 0.002 to 1.5, more preferably 0.005 to 1.2, and still more preferably 0.01 to 1.

### [Other Components]

The cleaning composition may contain other components in addition to the various components described above.

Examples of the other components include a pH adjusting agent, a surfactant, a fluorine compound, and a polymer.

The other components may be used alone or in combination of two or more kinds thereof.

### <pH Adjusting Agent>

Examples of the pH adjusting agent include a basic compound such as potassium hydroxide and an acidic compound such as nitric acid.

In addition, a pH of the cleaning composition may be adjusted by adjusting an addition amount of the various components which can be contained in the above-described cleaning composition. Specifically, the above-described amine compound and organic acid may be used for adjusting the pH of the cleaning composition.

A content of the pH adjusting agent can be appropriately adjusted according to the type and amount of other components and the pH of the desired cleaning composition.

### <Surfactant>

The surfactant is a compound having a hydrophilic group and a hydrophobic group in one molecule.

Examples of the surfactant include an anionic surfactant, a cationic surfactant, a nonionic surfactant, and an amphoteric surfactant.

Examples of the surfactant include surfactants described in paragraphs [0091] to [0109] of WO2021/054009A, the content of which is incorporated herein by reference.

A content of the surfactant is preferably 1.0% to 30.0% by mass, more preferably 5.0% to 20.0% by mass, and still more preferably 10.0% to 20.0% by mass with respect to the total mass of the cleaning composition.

### <Fluorine Compound>

Examples of the fluorine compound include compounds described in paragraphs [0013] to [0015] of JP2005-150236A, the content of which is incorporated herein by reference.

### <Polymer>

The polymer is preferably a water-soluble polymer.

The “water-soluble polymer” means a compound having two or more repeating units linked in a linear or mesh form through a covalent bond, and a polymer in which a mass dissolved in 100 g of water at 20° C. is 0.1 g or more.

Examples of the water-soluble polymer include polyacrylic acid, polymethacrylic acid, polymaleic acid, polyvinylsulfonic acid, and salts thereof; a copolymer of a monomer such as styrene, α-methylstyrene, and/or 4-methylstyrene and an acid monomer such as (meth)acrylic acid and/or maleic acid, and salts thereof; polyglycerin; vinyl-based synthetic polymers such as polyvinyl alcohol and polyoxyethylene; and a modified product of natural polysaccharides such as hydroxyethyl cellulose, carboxymethyl cellulose, and processed starch.

Examples of the polymer also include water-soluble polymers described in paragraphs [0043] to [0047] of JP2016-171294A, the content of which is incorporated herein by reference.

A content of the various components which can be contained in the above-described cleaning composition can be measured, for example, according to a known method such as gas chromatography-mass spectrometry (GC-MS), liquid chromatography-mass spectrometry (LC-MS), and ion-exchange chromatography (IC).

### [Physical Properties of Cleaning Composition]

<pH>

A pH of the cleaning composition is usually 1.0 to 14.0, preferably 2.0 to 13.5, more preferably 2.5 to 13.2, still more preferably 3.0 to 13.0, and particularly preferably 10.0 to 13.0.

The pH of the cleaning composition can be measured by a method based on JIS Z8802-1984 using a known pH meter. The above-described pH is a value at a measurement temperature of 25° C.

### <Content of Metal Impurities>

A content (measured as an ion concentration) of any metal impurities (metal elements of Fc, Co, Na, Cu, Mg, Mn, Li, Al, Cr, Ni, Zn, Sn, and Ag) is preferably 5 ppm by mass or less and more preferably 1 ppm by mass or less with respect to the total mass of the cleaning composition. From the viewpoint of applying to the manufacture of state-of-the-art semiconductor elements, the content of the above-described metal impurities is still more preferably 100 ppb by mass or less and particularly preferably less than 10 ppb by mass with respect to the total mass of the cleaning composition. The lower limit thereof is often 0 ppb by mass or more with respect to the total mass of the cleaning composition.

Examples of a method for reducing the metal content include performing a purifying treatment such as distillation and filtration using an ion exchange resin or a filter at a stage of raw materials used in the production of the cleaning composition or a stage after the production of the cleaning composition.

Examples of other methods for reducing the metal content include using a container with less elution of impurities, which will be described later, as a container that accommodates the raw material or the produced cleaning composition. In addition, examples thereof include lining an inner wall of the pipe with a fluororesin in order to prevent the elution of metal components from a pipe or the like during the production of the cleaning composition.

### <Inorganic Particles and Organic Particles>

The total content of inorganic particles and organic particles is preferably 1.0% by mass or less, more preferably 0.1% by mass or less, and still more preferably 0.01% by mass or less with respect to the total mass of the cleaning composition. The lower limit thereof is often 0% by mass by mass or more with respect to the total mass of the cleaning composition.

The inorganic particles and the organic particles contained in the cleaning composition correspond to, for example, particles such as organic solids and inorganic solids contained as impurities in raw materials, and particles such as organic solids and inorganic solids brought in as contaminants during the preparation of the cleaning composition, in which those particles are finally present as particles without being dissolved in the cleaning composition.

The content of the inorganic particles and the organic particles present in the cleaning composition can be measured in a liquid phase by using a commercially available measuring device in a light scattering type liquid particle measuring method using a laser as a light source.

Examples of a method for removing the inorganic particles and the organic particles include a purification treatment such as filtering, which will be described later.

### [Method for Producing Cleaning Composition]

Examples of a method for producing the cleaning composition include known production methods, and a production method including a liquid preparation step is preferable.

### [Liquid Preparation Step]

Examples of the liquid preparation step include a step of mixing the various components which can be contained in the above-described cleaning composition.

There is no particular limitation on the order or timing of mixing together the above-described various components. Examples of the liquid preparation step include a method of adding and stirring the various components in a container filled with purified pure water (ultrapure water) and preparing a liquid by adding the pH adjusting agent as necessary. The method of adding the pure water and each of the above-described various components to the container may be either batch addition or divided addition.

Examples of a stirring method in the liquid preparation step include a method of carrying out stirring using a known stirrer or a known disperser.

Examples of the above-described stirrer include an industrial mixer, a portable stirrer, a mechanical stirrer, and a magnetic stirrer. Examples of the above-described disperser include an industrial disperser, a homogenizer, an ultrasonic disperser, and a beads mill.

A storage temperature of the mixing of each of the above-described various components in the liquid preparation step, a purification treatment described below, and the produced cleaning composition is preferably 40° C. or lower and more preferably 30° C. or lower. The lower limit thereof is preferably 5° C. or higher and more preferably 10° C. or higher.

### <Purification Treatment>

It is preferable that at least one of raw materials of the various components which can be contained in the cleaning composition is subjected to a purification treatment before the liquid preparation step.

A purity of the raw material after the purification treatment is preferably 95% by mass or more and more preferably 98% by mass or more. The upper limit thereof is preferably 100% by mass or less and more preferably 99.9999% by mass or less.

Examples of the purification treatment include known methods such as a distillation treatment and a filtering treatment described below, for example, an ion exchange resin, a reverse osmosis membrane (RO membrane), and filtration.

The purification treatment may be carried out by combining a plurality of the above-described purification methods. For example, the raw materials are subjected to a primary purification treatment by passing through the RO membrane, and then the obtained raw materials are subjected to a secondary purification treatment by passing through a purification device consisting of a cation-exchange resin, an anion-exchange resin, or a mixed-bed type ion exchange resin. In addition, the purification treatment may be performed a plurality of times.

Examples of a filter used for the filtering include known filters for filtration.

From the viewpoint of being able to remove highly polar contaminants which tend to cause defects, examples of a material of the filter include fluororesins such as polytetrafluoroethylene (PTFE) and tetrafluoroethylene perfluoroalkyl vinyl ether copolymer (PFA), polyamide-based resins such as nylon, and polyolefin resins (including those with a high density and a ultra-high molecular weight) such as polyethylene and polypropylene (PP); and polyethylene, polypropylene (including high-density polypropylene), fluororesin (including PTFE and PFA), or polyamide resin (including nylon) is preferable, and fluororesin is more preferable.

A critical surface tension of the filter is preferably 70 to 95 mN/m and more preferably 75 to 85 mN/m. In a case where the critical surface tension is within the above-described range, it is possible to remove highly polar contaminants which tend to cause defects. As the critical surface tension of the filter, a nominal value of a manufacturer can be used.

A pore diameter of the filter is preferably 2 to 20 nm and more preferably 2 to 15 nm. In a case where the pore diameter of the filter is within the above-described range, it is possible to suppress filtration clogging and to remove fine foreign substances such as impurities and aggregates. As the pore diameter of the filter, a nominal value of a manufacturer can be used.

The filtering may be carried out once or twice or more.

In a case where the filtering is carried out twice or more, the filters used for the filtering may be the same or different from each other.

A temperature of the filtering is preferably 25° C. or lower, more preferably 23° C. or lower, and still more preferably 20° C. or lower. The lower limit thereof is preferably 0° C. or higher, more preferably 5° C. or higher, and still more preferably 10° C. or higher. In a case where the filtering is carried out in the above range, it is possible to remove foreign substances and impurities dissolved in the raw materials.

### <Container>

The cleaning composition (including the aspect of diluted cleaning composition described later) can be added in any container to be stored and transported as long as the container is not corroded.

In application for a semiconductor, the container is preferably a container which has a high degree of cleanliness inside the container and in which the elution of impurities from an inner wall of an accommodating portion of the container into the cleaning composition is suppressed.

Examples of the above-described container include a commercially available container for a semiconductor cleaning composition. Specific examples thereof include CLEAN BOTTLE series (manufactured by AICELLO CORPORATION) and PURE BOTTLE (manufactured by KODAMA PLASTICS Co., Ltd.).

In addition, the container is preferably a container in which a liquid contact portion with the cleaning composition, such as the inner wall of the accommodating portion of the container, is made of a fluororesin (perfluororesin) or metal subjected to an antirust treatment and a metal elution prevention treatment.

The inner wall of the container is preferably formed from at least one resin selected from the group consisting of a polyethylene resin, a polypropylene resin, and a polyethylene-polypropylene resin; another resin different from these resins; or a metal which has been subjected to an antirust treatment and a metal elution prevention treatment, such as stainless steel, Hastelloy, Inconel, and Monel.

The above-described different resin is preferably a fluororesin (perfluororesin).

With a container having an inner wall formed of a fluororesin is used, elution of ethylene and propylene oligomers can be further suppressed than in a case of a container having an inner wall formed of a polyethylene resin, a polypropylene resin, or a polyethylene-polypropylene resin.

Examples of the container having an inner wall formed of a fluororesin include a FluoroPure PFA composite drum (manufactured by Entegris, Inc.) and containers described JP1991-502677A (JP-H3-502677A), WO2004/016526A, and WO99/046309A.

In addition, other than the above-described fluororesin, it is also preferable that the inner wall of the container is made of quartz or a metal material finished up with electropolishing (electropolished metal material).

As a metal material used for producing the electropolished metal material, a metal material containing at least one selected from the group consisting of chromium and nickel, in which the total content of chromium and nickel is more than 25% by mass with respect to the total mass of the metal material, is preferable. Examples thereof include stainless steel and a nickel-chromium alloy.

The total content of chromium and nickel in the metal material is more preferably 30% by mass or more with respect to the total mass of the metal material. The upper limit thereof is preferably 90% by mass or less with respect to the total mass of the metal material.

Examples of a method of electropolishing the metal material include known methods, and specific examples thereof include methods described in paragraphs [0011] to [0014] of JP2015-227501A and paragraphs [0036] to [0042] of JP2008-264929A.

It is preferable that the inside of the container is cleaned before the container is filled with the cleaning composition.

Examples of the cleaning method include known methods. With regard to a liquid used for the cleaning, it is preferable that the amount of metal impurities in the liquid is reduced. The cleaning composition may be bottled in a container such as a gallon bottle and a coated bottle after the production, and then may be transported and stored.

From the viewpoint of preventing changes in components in the cleaning composition during storage, it is preferable that the inside of the container is replaced with inert gas (for example, nitrogen, argon, or the like) having a purity of 99.99995% by volume or more, and it is more preferable to use inert gas with a low moisture content.

A temperature for transportation and storage may be controlled to room temperature (25° C.) or −20° C. to 20° C.

### [Dilution Step]

The method for producing the cleaning composition may include a dilution step of diluting the cleaning composition obtained in the above-described liquid preparation step using a diluent such as water.

The diluted cleaning composition obtained in the above-described dilution step is one aspect of the cleaning composition according to the embodiment of the present invention as long as the requirements of the present invention are satisfied.

A dilution ratio of the diluted cleaning composition in the dilution step can be appropriately adjusted according to the type and content of the various components which can be contained in the cleaning composition, the semiconductor substrate as an object to be cleaned, and the like.

The dilution ratio of the diluted cleaning composition to the cleaning composition before the dilution is preferably 10 to 10,000 times, more preferably 20 to 3,000 times, and still more preferably 50 to 1,000 times, in terms of mass ratio or volume ratio (volume ratio at 23° C.).

The dilution step may be carried out according to the above-described liquid preparation step. Examples of a stirring device and a stirring method in the dilution step include the stirring device and the stirring method in the liquid preparation step described above.

It is preferable that the water used in the dilution step is subjected to the purification treatment before use. In addition, it is also preferable to carry out the purification treatment on the diluted cleaning composition obtained in the dilution step.

Examples of the purification treatment include the ion component reducing treatment using the ion exchange resin, the RO membrane, or the like, and the foreign matter removal using filtering, which are described as the purification treatment for the cleaning composition above, and it is preferable to carry out any one of these treatments.

### [Clean Room]

It is preferable that handlings such as production of the cleaning composition, opening and cleaning of the container, and filling of the cleaning composition, treatment analysis, and measurements are all performed in a clean room.

It is preferable that the clean room meets the 14644-1 clean room standard.

In addition, it is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Application of Cleaning Composition]

The cleaning composition is preferably used in a cleaning step of cleaning a semiconductor substrate, and more preferably used for cleaning a semiconductor substrate having copper, cobalt, or tungsten, which has been subjected to a CMP treatment. That is, the cleaning composition can also be used for cleaning a semiconductor substrate in a process of manufacturing a semiconductor substrate.

As described above, for the cleaning of the semiconductor substrate, the diluted cleaning composition obtained by diluting the cleaning composition may be used.

### [Object to be Cleaned]

Examples of an object to be cleaned with the cleaning composition include a semiconductor substrate having a metal film containing copper, cobalt, or tungsten on the semiconductor substrate.

In the present specification, the “on the semiconductor substrate” includes, for example, both the front and back surfaces, the side surfaces, and the inside of the groove of the semiconductor substrate. In addition, the metal film on the semiconductor substrate encompasses not only a case where the metal film is directly on the surface of the semiconductor substrate but also a case where the metal film is present on the semiconductor substrate through another layer.

Examples of a metal contained in the metal film include copper, cobalt, and tungsten.

The metal film may contain a metal other than copper, cobalt, and tungsten.

Examples of other metals include at least one metal M selected from the group consisting of titanium, tantalum, ruthenium, chromium, hafnium, osmium, platinum, nickel, manganese, zirconium, molybdenum, lanthanum, and iridium.

Examples of the semiconductor substrate which is the object to be cleaned with the cleaning composition include a substrate having a metal wiring line film, a barrier metal, and an insulating film on a surface of a wafer constituting the semiconductor substrate.

Examples of the wafer constituting the semiconductor substrate include a wafer consisting of a silicon-based material, such as a silicon (Si) wafer, a silicon carbide (SIC) wafer, and a silicon-including resin-based wafer (glass epoxy wafer), a gallium phosphorus wafer, a gallium arsenic wafer, and an indium phosphorus wafer.

Examples of the silicon wafer include an n-type silicon wafer in which a silicon wafer is doped with a pentavalent atom (for example, phosphorus (P), arsenic, antimony, or the like) and a p-type silicon wafer in which a silicon wafer is doped with a trivalent atom (for example, boron, gallium, or the like).

Examples of the silicon of the silicon wafer include amorphous silicon, single crystal silicon, polycrystalline silicon, and polysilicon.

As the above-described wafer, a wafer consisting of a silicon-based material, such as a silicon wafer, a silicon carbide wafer, and a resin-based wafer (a glass epoxy wafer) including silicon, is preferable.

The semiconductor substrate may further include an insulating film on the above-described wafer.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film).

Examples of the metal film containing copper (copper-containing film) include a metal film consisting of only metal copper (copper metal film), and a metal film made of an alloy consisting of copper and a metal other than copper (copper alloy metal film).

Examples of the copper alloy metal film include a copper-titanium alloy metal film and a copper-cobalt alloy metal film.

Examples of the metal film containing cobalt (cobalt-containing film) include a metal film consisting of only metal cobalt (cobalt metal film), and a metal film made of an alloy consisting of cobalt and a metal other than cobalt (cobalt alloy metal film).

Examples of the cobalt alloy metal film include a cobalt-titanium alloy metal film and a cobalt-tungsten alloy metal film.

Examples of the metal film containing tungsten (tungsten-containing film) include a metal film consisting of only metal tungsten (tungsten metal film), and a metal film made of an alloy consisting of tungsten and a metal other than tungsten (tungsten alloy metal film).

Examples of the tungsten alloy metal film include a tungsten-titanium alloy metal film and a tungsten-cobalt alloy metal film.

The tungsten-containing film can be used, for example, for a barrier metal or a via, and for a connecting portion between wiring lines.

Examples of a method of forming the above-described insulating film, the above-described copper-containing film, the above-described cobalt-containing film, and the above-described tungsten-containing film on the wafer constituting the semiconductor substrate include known methods.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method for forming the above-described copper-containing film, the above-described cobalt-containing film, and the above-described tungsten-containing film include a method of forming a circuit on the wafer having the above-described insulating film by a known method such as a resist, and then forming the copper-containing film, the cobalt-containing film, and the tungsten-containing film by a plating, a CVD method or the like.

### <CMP Treatment>

The CMP treatment is a treatment in which a surface of a substrate having the metal wiring line film, the barrier metal, and the insulating film is flattened by a combined action of a chemical action and a mechanical polishing using a polishing slurry including polishing fine particles (abrasive grains).

A surface of the semiconductor substrate, which has been subjected to the CMP treatment, may have impurities remaining thereon, such as abrasive grains (for example, silica and alumina) used in the CMP treatment, a polished metal wiring line film, and metal impurities (metal residue) derived from the barrier metal. In addition, organic impurities derived from the polishing slurry used in the CMP treatment may remain. For example, since these impurities may cause a short-circuit between wiring lines and deteriorate electrical characteristics of the semiconductor substrate, the semiconductor substrate which has been subjected to the CMP treatment is subjected to a cleaning treatment for removing these impurities from the surface.

Examples of the semiconductor substrate which has been subjected to the CMP treatment include substrates which have been subjected to the CMP treatment, described in Journal of the Japan Society for Precision Engineering, Vol. 84, No. 3, 2018.

It is preferable to use a polishing liquid in the CMP treatment.

Examples of the polishing liquid include a polishing liquid containing iron ions and hydrogen peroxide, and a polishing liquid containing chemically modified colloidal silica (for example, cation-modified or anion-modified colloidal silica).

As the above-described polishing liquid, a polishing liquid containing an iron complex, described in JP2020-068378A, JP2020-015899A, and U.S. Pat. No. 11,043,151B, or a polishing liquid containing chemically modified colloidal silica, described in JP2021-082645A, is preferable.

### <Buffing Treatment>

The surface of the semiconductor substrate which is the object to be cleaned by the cleaning composition may be subjected to the CMP treatment and then to a buffing treatment.

The buffing treatment is a treatment of reducing impurities on the surface of the semiconductor substrate using a polishing pad. Specifically, the surface of the semiconductor substrate which has been subjected to the CMP treatment is brought into contact with the polishing pad, and the semiconductor substrate and the polishing pad are relatively slid while supplying a composition for the buffing treatment to a contact portion. As a result, impurities on the surface of the semiconductor substrate are removed by a frictional force of the polishing pad and a chemical action of a composition for the buffing treatment.

As the composition for the buffing treatment, a known composition for the buffing treatment can be appropriately used depending on the type of the semiconductor substrate, and the type and amount of the impurities to be removed. Examples of components contained in the composition for a buffing treatment include a water-soluble polymer such as polyvinyl alcohol, water as a dispersion medium, and an acid such as nitric acid.

In addition, as the buffing treatment, it is preferable that the semiconductor substrate is buffed using the above-described cleaning composition as the composition for the buffing treatment.

A polishing device, polishing conditions, and the like, which are used in the buffing treatment, can be appropriately selected from known devices and conditions according to the type of the semiconductor substrate, the object to be removed, and the like. Examples of the buffing treatment include treatments described in paragraphs [0085] to [0088] of WO2017/169539A, the content of which is incorporated herein by reference.

### [Cleaning Method of Semiconductor Substrate]

The cleaning method of a semiconductor substrate preferably includes a cleaning step of cleaning the semiconductor substrate which has been subjected to the CMP treatment using the above-described cleaning composition.

The cleaning method of a semiconductor substrate also preferably includes a step of applying the diluted cleaning composition obtained in the above-described dilution step to the semiconductor substrate which has been subjected to the CMP treatment to carry out cleaning.

Examples of the cleaning step of cleaning a semiconductor substrate using the cleaning composition include a known cleaning method which is carried out on a CMP-treated semiconductor substrate.

Specifically, in scrub cleaning in which a cleaning member such as a brush is physically brought into contact with a surface of the semiconductor substrate while supplying the cleaning composition to the semiconductor substrate to remove residues, and in immersion-type cleaning such as an immersion in which a semiconductor substrate is immersed in the cleaning composition, a spinning (dropping) in which the cleaning composition is dropped while rotating a semiconductor substrate, and a spraying in which the cleaning composition is sprayed, from the viewpoint that the impurities remaining on the surface of the semiconductor substrate can be further reduced, it is preferable to carry out a ultrasonic treatment to the cleaning composition in which the semiconductor substrate is immersed.

The above-described cleaning step may be carried out once or twice or more. In a case of carrying out the cleaning twice or more, the same method may be repeated or different methods may be combined.

The cleaning method of a semiconductor substrate may be a single-wafer method or a batch method.

The single-wafer method is a method of treating semiconductor substrates one by one, and the batch method is a method of treating a plurality of semiconductor substrates at the same time.

A temperature of the cleaning composition used in for cleaning a semiconductor substrate is not particularly limited.

Examples of the temperature of the above-described cleaning composition include room temperature (25° C.), and from the viewpoint of improving cleaning performance, the temperature is preferably 10° C. to 60° C. and more preferably 15° C. to 50° C.

It is preferable that a pH of the cleaning composition and a pH of the diluted cleaning composition are each in the above-described suitable aspect of pH.

A cleaning time in the cleaning of the semiconductor substrate can be appropriately changed depending on the type, content, and the like of the components which can be contained in the cleaning composition. The above-described cleaning time is preferably 10 to 120 seconds, more preferably 20 to 90 seconds, and still more preferably 30 to 60 seconds.

A supply amount (supply rate) of the cleaning composition in the cleaning step of the semiconductor substrate is preferably 50 to 5,000 mL/min and more preferably 500 to 2,000 mL/min.

In the cleaning of the semiconductor substrate, a mechanical stirring method may be used in order to further improve cleaning performance of the cleaning composition.

Examples of the mechanical stirring method include a method of circulating the cleaning composition on the semiconductor substrate, a method of flowing or spraying the cleaning composition on the semiconductor substrate, and a method of stirring the cleaning composition with ultrasonic or megasonic.

After the above-described cleaning of the semiconductor substrate, a rinsing step of rinsing and washing the semiconductor substrate with a solvent may be carried out.

The rinsing step is continuously carried out after the cleaning step of the semiconductor substrate, and a step of rinsing the semiconductor substrate with a rinsing liquid for 5 to 300 seconds is preferable. The rinsing step may be carried out using the above-described mechanical stirring method.

Examples of the rinsing liquid include water (preferably deionized water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (for example, aqueous ammonium hydroxide which has been diluted, or the like) may be used.

Examples of the method of bringing the rinsing solvent into contact with the semiconductor substrate include the above-described method of bringing the cleaning composition into contact with the cleaning composition.

After the above-described rinsing step, a drying step of drying the semiconductor substrate may be carried out.

Examples of the drying method include a spin drying method, a method of flowing a dry gas onto a semiconductor substrate, a method of heating a substrate by a heating unit such as a hot plate and an infrared lamp, a Marangoni drying method, a Rotagoni drying method, an isopropyl alcohol (IPA) drying method, and a method of combining these methods.

### EXAMPLES

Hereinafter, the present invention will be described in detail with reference to Examples.

The materials, the amounts of the materials to be used, the proportions, and the like shown in Examples may be modified as appropriate as long as the modifications do not depart from the spirit of the present invention.

In Examples and Comparative Examples, a pH of the cleaning composition was measured at 25° C. using a pH meter (F-74, manufactured by HORIBA, Ltd.) in accordance with JIS Z8802-1984. In addition, a pKa of a conjugate acid of the compound X was a value in water (temperature: 25° C.) calculated using Calculator Plugins (manufactured by Fujitsu Ltd.).

In the production of cleaning compositions of Examples and Comparative Examples, all of handling of a container, and production, filling, storage, and analytical measurement of the cleaning compositions were performed in a clean room satisfying a level of ISO Class 2 or lower.

### [Various Components of Cleaning Composition]

A cleaning composition was prepared using the following various components.

As various components used in Examples, those all classified into a semiconductor grade or a high-purity grade equivalent thereto were used.

The pKa of the compound X and the pKa of the compound Y are both pKa of a conjugate acid.

### [Amine Compound]

### <Compound X>

DMAMP: 2-dimethylamino-2-methyl-1-propanol (pKa=10.2)
TMEN: N,N,N′,N′-tetramethylethylenediamine (pKa=10.4)
TMPN: N,N,N′,N′-tetramethyl-1,3-propanediamine (pKa=10.3)
THEMAH: tris(2-hydroxyethyl)methylammonium hydroxide
ETMAH: ethyltrimethylammonium hydroxide
Choline: 2-hydroxyethyltrimethylammonium hydroxide
DMBHEH: dimethylbis(2-hydroxyethyl) ammonium hydroxide
TEAH: tetraethylammonium hydroxide
TBAH: tetrabutylammonium hydroxide
PMDETA: N,N,N′,N″,N″-pentamethyldiethylenetriamine (pKa=8.8)
MDEA: methyldiethanolamine (pKa=8.6)

### <Compound Y>

TEA: triethanolamine (pKa=7.8)
AMP: 2-amino-2-methyl-1-propanol (pKa=9.8)
ethylamine: ethylamine (pKa=10.7)
AEE: 2-(2-aminoethylamino)ethanol (pKa=9.8)
TMAH: tetramethylammonium hydroxide

### [Anticorrosion Agent]

Adenine: adenine
1,2,3-triazole: 1,2,3-triazole
Guanine: guanine
Adenosine: adenosine
Benzimidazole: benzimidazole
5-aminotetrazole: 5-aminotetrazole
3,5-dimethylpyrazole: 3,5-dimethylpyrazole
Kinetin: kinetin

### [Organic Solvent]

MMB: 3-methoxy-3-methyl-1-butanol (boiling point: 174° C., molecular weight: 118.2)
DPGBE: dipropylene glycol butyl ether (boiling point: 230° C., molecular weight: 190.3)
EGEEA: ethylene glycol monoethyl ether acetate (boiling point: 145° C., molecular weight: 132.2)
BP: 1-butoxy-2-propanol (boiling point: 170° C., molecular weight: 132.2)
ISOBEoH: 2-isobutoxyethanol (boiling point: 160° C., molecular weight: 118.2)
DMSO: dimethyl sulfoxide (boiling point: 189° C., molecular weight: 78.1)
Sulfolane: sulfolane (boiling point: 285° C., molecular weight: 120.2)
EGME: ethylene glycol monomethyl ether (boiling point: 124° C., molecular weight: 76.1)
EGBE: ethylene glycol monobutyl ether (boiling point: 171° C., molecular weight: 118.2)
DEGBE: 2-methyl-2,4-pentanediol (boiling point: 197° C., molecular weight: 118.2)
PC: propylene carbonate (boiling point: 242° C., molecular weight: 102.1)
CHN: cyclohexanone (boiling point: 153° C., molecular weight: 98.1)

### [Organic Acid]

SA: succinic acid
OA: oxalic acid
MA: malonic acid
LA: lactic acid
GA: glutaric acid
AA: adipic acid

### [pH Adjusting Agent]

Potassium hydroxide or nitric acid

### [Water]

Ultrapure water

### [Preparation of Cleaning Composition]

A cleaning composition of Example 1 was prepared by the following procedure.

The cleaning composition of Example 1 was obtained by adding DMAMP, Adenine, and MMB to ultrapure water so that contents shown in the table were obtained, further adding potassium hydroxide or nitric acid so that the pH shown in the table was obtained, and sufficiently stirring the mixture. Cleaning compositions other than Example 1 were prepared with reference to the preparation method of the cleaning composition of Example 1.

In any of the cleaning compositions, the content of the pH adjusting agent was set to 2% by mass or less with respect to the total mass of the cleaning composition.

In Example 49, the pH was adjusted to the pH shown in the table using tetramethylammonium hydroxide, without using potassium hydroxide or nitric acid as the pH adjusting agent.

### [Evaluation]

### [Removability of Organic Residues and Removability of Inorganic Residues]

Removability of organic residues and removability of inorganic residues were evaluated by the following procedure.

### <Polishing Device>

As a polishing device, a device “FREX300II” manufactured by EBARA CORPORATION was used, and each sample was polished under the following polishing conditions while supplying a polishing liquid.
Table rotation speed: 80 rpm
Head rotation speed: 78 rpm
Polishing pressure: 120 hPa
Polishing pad: manufactured by Rodel-Nitta, IC1400
Polishing liquid supply speed: 250 mL/min

12-inch wafers on which Cu, Co, or W was formed on a Si substrate were prepared separately. Each Si substrate obtained above was polished for 10 seconds using the above-described polishing device under the above-described polishing conditions, using CSL9044 (manufactured by FUJIFILM Corporation) as the polishing liquid in a case of Cu and Co, thereby equalizing a micro roughness of a polished surface. Furthermore, the Si substrate was polished for 30 seconds using the above-described polishing device under the above-described polishing conditions, using CBSL8301C (manufactured by FUJIFILM Corporation) as the polishing liquid. In a case of W, the Si substrate was polished for 60 seconds using FSL3400 (manufactured by FUJIFILM Corporation) as the polishing liquid. After the polishing, using the cleaning composition of each of Examples and Comparative Examples, cleaning was performed for 60 seconds using a cleaning unit 1 (sheet-type cleaning with a brush scrub), and cleaning was performed for 30 seconds using a cleaning unit 2 (sheet-type cleaning with a brush scrub). Thereafter, rinsing was performed for 60 seconds using water as a rinsing liquid, and finally, spin drying was performed at a rotation speed of 1000 rpm while blowing nitrogen gas onto the surface of the wafer in the cleaning unit 2, and the wafer was dried out to obtain a sample for removability evaluation. The working environment was in a clean room and under a condition of room temperature of 23° C.

The number of defects of the wafer obtained with each metal species was confirmed by a defect inspection device (ComPlus II). The defect inspection device was used for specifying a defect having a size of 0.1 μm by using scattered light, and finally, the defect type was also specified using Review SEM/EDAX (scanning electron microscope/energy-dispersive X-ray analysis) of the defect. The removability of each residue with respect to the defect was evaluated according to the following evaluation standard.

### <Evaluation Standard of Removability of Organic Residues>

A: number of defects of the organic residues on the substrate was less than 5 pieces/Wf.
B: number of defects of the organic residues on the substrate was 5 pieces/Wf or more and less than 10 pieces/Wf.
C: number of defects of the organic residues on the substrate was 10 pieces/Wf or more and less than 30 pieces/Wf.
D: number of defects of the organic residues on the substrate was 30 pieces/Wf or more and less than 50 pieces/Wf.
E: number of defects of the organic residues on the substrate was 50 pieces/Wf or more.

### <Evaluation Standard of Removability of Inorganic Residues>

A: number of defects of the inorganic residues on the substrate was less than 10 pieces/Wf.
B: number of defects of the inorganic residues on the substrate was 10 pieces/Wf or more and less than 30 pieces/Wf.
C: number of defects of the inorganic residues on the substrate was 30 pieces/Wf or more and less than 50 pieces/Wf.
D: number of defects of the inorganic residues on the substrate was 50 pieces/Wf or more.

### [Surface Roughness]

First, 12-inch wafers on which Cu, Co, or W was formed were separately treated by the same procedure as the evaluation of the removability of the organic residues and the evaluation of the removability of the inorganic residues described above. Using an atomic force microscope (AFM), surface roughness was evaluated at a center position and a position 5 mm from an edge of the obtained wafer, respectively, in three trials. A measurement area of the AFM was 10 μm square, and the level of the surface roughness was confirmed. In a case where only water cleaning was performed without using the cleaning composition, an average surface roughness Ra was 0.20.

### <Evaluation Standard of Cu or Co Surface Roughness>

A: average surface roughness Ra was less than 0.21.
B: average surface roughness Ra was 0.21 or more and less than 0.25.
C: average surface roughness Ra was 0.25 or more and less than 0.30.
D: average surface roughness Ra was 0.30 or more and less than 0.35.
E: average surface roughness Ra was 0.35 or more.

### <Evaluation Standard of Surface Roughness/W>

A: average surface roughness Ra was less than 0.30.
B: average surface roughness Ra was 0.30 or more and less than 0.35.
C: average surface roughness Ra was 0.35 or more and less than 0.40.
D: average surface roughness Ra was 0.40 or more and less than 0.45.
E: average surface roughness Ra was 0.45 or more.

### [Result]

In the tables, the column of “Content (% by mass)” of various components indicates the content (% by mass) of the various components with respect to the total mass of the cleaning composition.

The column of “Remainder” in “Water” indicates a value obtained by subtracting, from 100% by mass, the total content of the various components contained in the cleaning composition other than water, which is shown in the tables.

“*1” in the column of “pH adjusting agent” means that the above-described pH adjusting agent was added in an amount such that the pH of the finally obtained cleaning composition was the numerical value in the column of “pH”. As described above, in Example 49, the pH was adjusted to the pH shown in the table using tetramethylammonium hydroxide, without using potassium hydroxide or nitric acid as the pH adjusting agent.

“Compound X/organic solvent” indicates a mass ratio of the content of the compound X to the content of the organic solvent.

“Compound Y/organic solvent” indicates a mass ratio of the content of the compound Y to the content of the organic solvent.

“Organic acid/organic solvent” indicates a mass ratio of the content of the organic acid to the content of the organic solvent.

“Anticorrosion agent/organic solvent” indicates a mass ratio of the content of the anticorrosion agent to the content of the organic solvent.

In the column of “Type” of the various components, in a case where two or more compound names are described, it indicates that each compound was used with the content in the right column. Specifically, in the column of the type of the organic solvent of Example 41, “MMB” and “EGBE” are described, which indicates that MMB was contained in an amount of 2.5% by mass and EGBE was contained in an amount of 2.5% by mass.

Table 2 is a continuation of Table 1, Table 4 is a continuation of Table 3, Table 6 is a continuation of Table 5, and Table 8 is a continuation of Table 7.

TABLE 1

| | Compound X | | | | | | | |
|---|---|---|---|---|---|---|---|---|
| | | | | | Total | Compound Y | | |
| | | Content | | Content | content | | Content | Anticorrosion |
| | | (% by | | (% by | (% by | | (% by | agent |
| | Type | mass) | Type | mass) | mass) | Type | mass) | Type |
| Example | DMAMP | 4 | — | — | 4 | | | Adenine |
| 1 | | | | | | | | |
| Example | TMEN | 4 | — | — | 4 | — | — | Adenine |
| 2 | | | | | | | | |
| Example | TMPN | 4 | — | — | 4 | — | — | Adenine |
| 3 | | | | | | | | |
| Example | THEMAH | 4 | — | — | 4 | — | — | Adenine |
| 4 | | | | | | | | |
| Example | ETMAH | 4 | — | — | 4 | — | — | Adenine |
| 5 | | | | | | | | |
| Example | Choline | 4 | — | — | 4 | — | — | Adenine |
| 6 | | | | | | | | |
| Example | DMBHEH | 4 | — | — | 4 | — | — | Adenine |
| 7 | | | | | | | | |
| Example | TEAH | 4 | — | — | 4 | — | — | Adenine |
| 8 | | | | | | | | |
| Example | TBAH | 4 | — | — | 4 | — | — | Adenine |
| 9 | | | | | | | | |
| Example | DMAMP | 4 | — | — | 4 | AMP | 0.01 | Adenine |
| 10 | | | | | | | | |
| Example | DMAMP | 4 | — | — | 4 | AMP | 0.03 | Adenine |
| 11 | | | | | | | | |
| Example | DMAMP | 4 | — | — | 4 | AMP | 0.1 | Adenine |
| 12 | | | | | | | | |
| Example | DMAMP | 4 | — | — | 4 | AMP | 0.5 | Adenine |
| 13 | | | | | | | | |
| Example | DMAMP | 4 | — | — | 4 | AMP | 2 | Adenine |
| 14 | | | | | | | | |
| Example | DMAMP | 4 | — | — | 4 | AMP | 5 | Adenine |
| 15 | | | | | | | | |
| Example | DMAMP | 4 | — | — | 4 | AMP | 10 | Adenine |
| 16 | | | | | | | | |
| Example | DMAMP | 4 | — | — | 4 | ethylamine | 0.5 | Adenine |
| 17 | | | | | | | | |
| Example | DMAMP | 4 | — | — | 4 | AEE | 0.1 | Adenine |
| 18 | | | | | | | | |
| Example | DMAMP | 4 | MDEA | 0.5 | 4.5 | — | — | Adenine |
| 19 | | | | | | | | |
| Example | DMAMP | 2 | TMEN | 2 | 4 | — | — | Adenine |
| 20 | | | | | | | | |
| Example | DMAMP | 2 | TMPN | 2 | 4 | — | — | Adenine |
| 21 | | | | | | | | |
| Example | TMPN | 4 | PMDETA | 1.5 | 5.5 | — | — | Adenine |
| 22 | | | | | | | | |
| Example | DMAMP | 4 | PMDETA | 1.5 | 5.5 | AMP | 0.1 | Adenine |
| 23 | | | | | | | | |
| Example | TMEN | 4 | PMDETA | 1.5 | 5.5 | — | — | Adenine |
| 24 | | | | | | | | |
| Example | THEMAH | 4 | MDEA | 0.5 | 4.5 | — | — | Adenine |
| 25 | | | | | | | | |
| Example | TEAH | 4 | MDEA | 0.5 | 4.5 | — | — | Adenine |
| 26 | | | | | | | | |

| | Anticorrosion | Organic | | | | | | |
|---|---|---|---|---|---|---|---|---|
| | agent | solvent | | Organic acid | | | | |
| | Content | | Content | | Content | pH | | |
| | (% by | | (% by | | (% by | adjusting | | |
| | mass) | Type | mass) | Type | mass) | agent | Water | pH |
| Example | 0.2 | MMB | 5 | — | — | *1 | Remainder | 11.5 |
| 1 | | | | | | | | |
| Example | 0.2 | MMB | 5 | — | — | *1 | Remainder | 11.6 |
| 2 | | | | | | | | |
| Example | 0.2 | MMB | 5 | — | — | *1 | Remainder | 11.4 |
| 3 | | | | | | | | |
| Example | 0.2 | MMB | 5 | — | — | *1 | Remainder | 13.2 |
| 4 | | | | | | | | |
| Example | 0.2 | MMB | 5 | — | — | *1 | Remainder | 13.0 |
| 5 | | | | | | | | |
| Example | 0.2 | MMB | 5 | — | — | *1 | Remainder | 13.1 |
| 6 | | | | | | | | |
| Example | 0.2 | MMB | 5 | — | — | *1 | Remainder | 13.0 |
| 7 | | | | | | | | |
| Example | 0.2 | MMB | 5 | — | — | *1 | Remainder | 13.3 |
| 8 | | | | | | | | |
| Example | 0.2 | MMB | 5 | — | — | *1 | Remainder | 13.3 |
| 9 | | | | | | | | |
| Example | 0.2 | MMB | 5 | — | — | *1 | Remainder | 11.5 |
| 10 | | | | | | | | |
| Example | 0.2 | MMB | 5 | — | — | *1 | Remainder | 11.5 |
| 11 | | | | | | | | |
| Example | 0.2 | MMB | 5 | — | — | *1 | Remainder | 11.5 |
| 12 | | | | | | | | |
| Example | 0.2 | MMB | 5 | — | — | *1 | Remainder | 11.5 |
| 13 | | | | | | | | |
| Example | 0.2 | MMB | 5 | — | — | *1 | Remainder | 11.5 |
| 14 | | | | | | | | |
| Example | 0.2 | MMB | 5 | — | — | *1 | Remainder | 11.5 |
| 15 | | | | | | | | |
| Example | 0.2 | MMB | 5 | — | — | *1 | Remainder | 11.5 |
| 16 | | | | | | | | |
| Example | 0.2 | MMB | 5 | — | — | *1 | Remainder | 11.5 |
| 17 | | | | | | | | |
| Example | 0.2 | MMB | 5 | — | — | *1 | Remainder | 11.5 |
| 18 | | | | | | | | |
| Example | 0.2 | MMB | 5 | — | — | *1 | Remainder | 11.5 |
| 19 | | | | | | | | |
| Example | 0.2 | MMB | 5 | — | — | *1 | Remainder | 11.5 |
| 20 | | | | | | | | |
| Example | 0.2 | MMB | 5 | — | — | *1 | Remainder | 11.5 |
| 21 | | | | | | | | |
| Example | 0.2 | MMB | 5 | — | — | *1 | Remainder | 11.5 |
| 22 | | | | | | | | |
| Example | 0.2 | MMB | 5 | — | — | *1 | Remainder | 11.5 |
| 23 | | | | | | | | |
| Example | 0.2 | MMB | 5 | — | — | *1 | Remainder | 11.5 |
| 24 | | | | | | | | |
| Example | 0.2 | MMB | 5 | — | — | *1 | Remainder | 12.8 |
| 25 | | | | | | | | |
| Example | 0.2 | MMB | 5 | — | — | *1 | Remainder | 13.1 |
| 26 | | | | | | | | |

TABLE 2

| | | | | | Cu evaluation result | | |
|---|---|---|---|---|---|---|---|
| | | | | | | | Suppression |
| | Compound | Compound | Organic | Anticorrosion | Removability | Removability | property of |
| | X/organic | Y/organic | acid/organic | agent/organic | of organic | of inorganic | surface |
| | solvent | solvent | solvent | solvent | residues | residues | roughness |
| Example 1 | 0.8 | — | — | 0.04 | C | C | A |
| Example 2 | 0.8 | — | — | 0.04 | C | C | A |
| Example 3 | 0.8 | — | — | 0.04 | C | C | A |
| Example 4 | 0.8 | — | — | 0.04 | C | C | A |
| Example 5 | 0.8 | — | — | 0.04 | C | C | A |
| Example 6 | 0.8 | — | — | 0.04 | C | C | A |
| Example 7 | 0.8 | — | — | 0.04 | C | C | A |
| Example 8 | 0.8 | — | — | 0.04 | C | C | A |
| Example 9 | 0.8 | — | — | 0.04 | C | C | A |
| Example 10 | 0.8 | 0.002 | — | 0.04 | C | C | A |
| Example 11 | 0.8 | 0.006 | — | 0.04 | B | B | A |
| Example 12 | 0.8 | 0.02 | — | 0.04 | B | B | A |
| Example 13 | 0.8 | 0.1 | — | 0.04 | B | B | A |
| Example 14 | 0.8 | 0.4 | — | 0.04 | B | B | A |
| Example 15 | 0.8 | 1 | — | 0.04 | B | B | A |
| Example 16 | 0.8 | 2 | — | 0.04 | B | B | B |
| Example 17 | 0.8 | 0.1 | — | 0.04 | B | B | A |
| Example 18 | 0.8 | 0.02 | — | 0.04 | A | A | B |
| Example 19 | 0.9 | — | — | 0.04 | B | B | A |
| Example 20 | 0.8 | — | — | 0.04 | B | B | A |
| Example 21 | 0.8 | — | — | 0.04 | B | B | A |
| Example 22 | 1.1 | — | — | 0.04 | B | B | A |
| Example 23 | 1.1 | 0.02 | — | 0.04 | B | B | A |
| Example 24 | 1.1 | — | — | 0.04 | B | B | A |
| Example 25 | 0.9 | — | — | 0.04 | B | B | A |
| Example 26 | 0.9 | — | — | 0.04 | B | B | A |

| | Co evaluation result | | | W evaluation result | | |
|---|---|---|---|---|---|---|
| | | | Suppression | | | Suppression |
| | Removability | Removability | property of | Removability | Removability | property of |
| | of organic | of inorganic | surface | of organic | of inorganic | surface |
| | residues | residues | roughness | residues | residues | roughness |
| Example 1 | C | C | A | C | C | B |
| Example 2 | C | C | A | C | C | B |
| Example 3 | C | C | A | C | C | B |
| Example 4 | C | C | A | C | C | B |
| Example 5 | C | C | A | C | C | B |
| Example 6 | C | C | A | C | C | B |
| Example 7 | C | C | A | C | C | B |
| Example 8 | C | C | A | C | C | B |
| Example 9 | C | C | A | C | C | B |
| Example 10 | C | C | A | C | C | B |
| Example 11 | B | B | A | B | B | B |
| Example 12 | B | B | A | B | B | B |
| Example 13 | B | B | A | B | B | B |
| Example 14 | B | B | A | B | B | B |
| Example 15 | B | B | A | B | B | B |
| Example 16 | B | B | B | B | B | C |
| Example 17 | B | B | A | B | B | B |
| Example 18 | A | A | B | A | A | C |
| Example 19 | B | B | A | B | B | B |
| Example 20 | B | B | A | B | B | B |
| Example 21 | B | B | A | B | B | B |
| Example 22 | B | B | A | B | B | B |
| Example 23 | B | B | A | B | B | B |
| Example 24 | B | B | A | B | B | B |
| Example 25 | B | B | A | B | B | B |
| Example 26 | B | B | A | B | B | B |

TABLE 3

| | Compound X | | | | | | | |
|---|---|---|---|---|---|---|---|---|
| | | | | | Total | Compound Y | | |
| | | Content | | Content | content | | Content | |
| | | (% by | | (% by | (% by | | (% by | Anticorrosion agent |
| | Type | mass) | Type | mass) | mass) | Type | mass) | Type |
| Example | THEMAH | 4 | MDEA | 0.5 | 4.5 | — | — | 1,2,3-triazole |
| 27 | | | | | | | | |
| Example | THEMAH | 4 | MDEA | 0.5 | 4.5 | — | — | Guanine |
| 28 | | | | | | | | |
| Example | THEMAH | 4 | MDEA | 0.5 | 4.5 | — | — | Adenosine |
| 29 | | | | | | | | |
| Example | THEMAH | 4 | MDEA | 0.5 | 4.5 | — | — | Benzimidazole |
| 30 | | | | | | | | |
| Example | THEMAH | 4 | MDEA | 0.5 | 4.5 | — | — | 5-aminotetrazole |
| 31 | | | | | | | | |
| Example | THEMAH | 4 | MDEA | 0.5 | 4.5 | — | — | 3,5-dimethylpyrazole |
| 32 | | | | | | | | |
| Example | THEMAH | 4 | MDEA | 0.5 | 4.5 | — | — | Kinetin |
| 33 | | | | | | | | |
| Example | DMAMP | 4 | PMDETA | 1.5 | 5.5 | AMP | 0.1 | Adenine |
| 34 | | | | | | | | |
| Example | DMAMP | 4 | PMDETA | 1.5 | 5.5 | AMP | 0.1 | Adenine |
| 35 | | | | | | | | |
| Example | DMAMP | 4 | PMDETA | 1.5 | 5.5 | AMP | 0.1 | Adenine |
| 36 | | | | | | | | |
| Example | DMAMP | 4 | PMDETA | 1.5 | 5.5 | AMP | 0.1 | Adenine |
| 37 | | | | | | | | |
| Example | DMAMP | 4 | PMDETA | 1.5 | 5.5 | AMP | 0.1 | Adenine |
| 38 | | | | | | | | |
| Example | DMAMP | 4 | PMDETA | 1.5 | 5.5 | AMP | 0.1 | Adenine |
| 39 | | | | | | | | |
| Example | THEMAH | 4 | MDEA | 0.5 | 4.5 | — | — | Adenine |
| 40 | | | | | | | | |
| Example | THEMAH | 4 | MDEA | 0.5 | 4.5 | — | — | Adenine |
| 41 | | | | | | | | |
| Example | THEMAH | 4 | MDEA | 0.5 | 4.5 | — | — | Adenine |
| 42 | | | | | | | | |
| Example | THEMAH | 4 | MDEA | 0.5 | 4.5 | — | — | Adenine |
| 43 | | | | | | | | |
| Example | THEMAH | 4 | MDEA | 0.5 | 4.5 | — | — | Adenine |
| 44 | | | | | | | | |
| Example | THEMAH | 4 | MDEA | 0.5 | 4.5 | — | — | Adenine |
| 45 | | | | | | | | |
| Example | THEMAH | 4 | MDEA | 0.5 | 4.5 | — | — | Adenine |
| 46 | | | | | | | | |
| Example | THEMAH | 4 | MDEA | 0.5 | 4.5 | — | — | Adenine |
| 47 | | | | | | | | |
| Example | THEMAH | 4 | MDEA | 0.5 | 4.5 | — | — | Adenine |
| 48 | | | | | | | | |
| Example | THEMAH | 4 | MDEA | 0.5 | 4.5 | TMAH | 0.5 | Adenine |
| 49 | | | | | | | | |
| Example | THEMAH | 4 | MDEA | 0.5 | 4.5 | — | — | Adenine |
| 50 | | | | | | | | |

| | Anticorrosion agent | Organic solvent | | Organic acid | | | | |
|---|---|---|---|---|---|---|---|---|
| | Content | | Content | | (% by | pH | | |
| | (% by | | (% by | | Content | adjusting | | |
| | mass) | Type | mass) | Type | mass) | agent | Water | pH |
| Example | 0.5 | MMB | 5 | — | — | *1 | Remainder | 12.8 |
| 27 | | | | | | | | |
| Example | 0.2 | MMB | 5 | — | — | *1 | Remainder | 12.8 |
| 28 | | | | | | | | |
| Example | 0.3 | MMB | 5 | — | — | *1 | Remainder | 12.8 |
| 29 | | | | | | | | |
| Example | 0.2 | MMB | 5 | — | — | *1 | Remainder | 12.8 |
| 30 | | | | | | | | |
| Example | 0.2 | MMB | 5 | — | — | *1 | Remainder | 12.8 |
| 31 | | | | | | | | |
| Example | 0.2 | Sulfolane | 5 | — | — | *1 | Remainder | 12.8 |
| 32 | | | | | | | | |
| Example | 0.2 | MMB | 5 | — | — | *1 | Remainder | 12.8 |
| 33 | | | | | | | | |
| Example | 0.2 | MMB | 5 | SA | 0.1 | *1 | Remainder | 11.5 |
| 34 | | | | | | | | |
| Example | 0.2 | MMB | 5 | OA | 0.1 | *1 | Remainder | 11.5 |
| 35 | | | | | | | | |
| Example | 0.2 | MMB | 5 | MA | 0.1 | *1 | Remainder | 11.5 |
| 36 | | | | | | | | |
| Example | 0.2 | MMB | 5 | LA | 0.1 | *1 | Remainder | 11.5 |
| 37 | | | | | | | | |
| Example | 0.2 | MMB | 5 | GA | 0.1 | *1 | Remainder | 11.5 |
| 38 | | | | | | | | |
| Example | 0.2 | MMB | 5 | AA | 0.1 | *1 | Remainder | 11.5 |
| 39 | | | | | | | | |
| Example | 0.2 | MMB | 5 | SA | 0.1 | *1 | Remainder | 11.5 |
| 40 | | | | | | | | |
| Example | 0.2 | MMB | 2.5 | SA | 0.1 | *1 | Remainder | 11.5 |
| 41 | | EGBE | 2.5 | | | | | |
| Example | 0.2 | MMB | 2.5 | SA | 0.1 | *1 | Remainder | 11.5 |
| 42 | | DMSO | 2.5 | | | | | |
| Example | 0.2 | EGBE | 2.5 | SA | 0.1 | *1 | Remainder | 11.5 |
| 43 | | DEGBE | 2.5 | | | | | |
| Example | 0.2 | DPGBE | 5 | SA | 0.1 | *1 | Remainder | 11.5 |
| 44 | | | | | | | | |
| Example | 0.2 | EGEEA | 5 | SA | 0.1 | *1 | Remainder | 11.5 |
| 45 | | | | | | | | |
| Example | 0.2 | BP | 5 | SA | 0.1 | *1 | Remainder | 11.5 |
| 46 | | | | | | | | |
| Example | 0.2 | ISOBEoH | 5 | SA | 0.1 | *1 | Remainder | 11.5 |
| 47 | | | | | | | | |
| Example | 0.2 | DMSO | 5 | SA | 0.1 | *1 | Remainder | 11.5 |
| 48 | | | | | | | | |
| Example | 0.2 | DMSO | 5 | SA | 0.1 | — | Remainder | 11.5 |
| 49 | | | | | | | | |
| Example | 0.2 | Sulfolane | 5 | SA | 0.1 | *1 | Remainder | 11.5 |
| 50 | | | | | | | | |

TABLE 4

| | | | | | Cu evaluation result | | |
|---|---|---|---|---|---|---|---|
| | | | | | | | Suppression |
| | Compound | Compound | Organic | Anticorrosion | Removability | Removability | property of |
| | X/organic | Y/organic | acid/organic | agent/organic | of organic | of inorganic | surface |
| | solvent | solvent | solvent | solvent | residues | residues | roughness |
| Example 27 | 0.9 | — | — | 0.1 | B | B | B |
| Example 28 | 0.9 | — | — | 0.04 | B | B | A |
| Example 29 | 0.9 | — | — | 0.06 | B | B | A |
| Example 30 | 0.9 | — | — | 0.04 | B | B | B |
| Example 31 | 0.9 | — | — | 0.04 | B | B | B |
| Example 32 | 0.9 | — | — | 0.04 | B | B | B |
| Example 33 | 0.9 | — | — | 0.04 | B | B | A |
| Example 34 | 1.1 | 0.02 | 0.02 | 0.04 | A | A | A |
| Example 35 | 1.1 | 0.02 | 0.02 | 0.04 | A | A | A |
| Example 36 | 1.1 | 0.02 | 0.02 | 0.04 | A | A | A |
| Example 37 | 1.1 | 0.02 | 0.02 | 0.04 | A | B | A |
| Example 38 | 1.1 | 0.02 | 0.02 | 0.04 | A | A | A |
| Example 39 | 1.1 | 0.02 | 0.02 | 0.04 | A | A | A |
| Example 40 | 0.9 | — | 0.02 | 0.04 | A | A | A |
| Example 41 | 0.9 | — | 0.02 | 0.04 | A | A | A |
| Example 42 | 0.9 | — | 0.02 | 0.04 | A | A | A |
| Example 43 | 0.9 | — | 0.02 | 0.04 | A | A | A |
| Example 44 | 0.9 | — | 0.02 | 0.04 | A | A | A |
| Example 45 | 0.9 | — | 0.02 | 0.04 | A | A | A |
| Example 46 | 0.9 | — | 0.02 | 0.04 | A | A | A |
| Example 47 | 0.9 | — | 0.02 | 0.04 | A | A | A |
| Example 48 | 0.9 | — | 0.02 | 0.04 | A | A | A |
| Example 49 | 0.9 | 0.1 | 0.02 | 0.04 | A | A | A |
| Example 50 | 0.9 | — | 0.02 | 0.04 | A | A | A |

| | Co evaluation result | | | W evaluation result | | |
|---|---|---|---|---|---|---|
| | | | Suppression | | | Suppression |
| | Removability | Removability | property of | Removability | Removability | property of |
| | of organic | of inorganic | surface | of organic | of inorganic | surface |
| | residues | residues | roughness | residues | residues | roughness |
| Example 27 | B | B | B | B | B | C |
| Example 28 | B | B | A | B | B | B |
| Example 29 | B | B | A | B | B | B |
| Example 30 | B | B | B | B | B | C |
| Example 31 | B | B | B | B | B | C |
| Example 32 | B | B | B | B | B | C |
| Example 33 | B | B | A | B | B | B |
| Example 34 | A | A | A | A | A | B |
| Example 35 | A | A | A | A | A | B |
| Example 36 | A | A | A | A | A | B |
| Example 37 | A | B | A | A | B | B |
| Example 38 | A | A | A | A | A | B |
| Example 39 | A | A | A | A | A | B |
| Example 40 | A | A | A | A | A | B |
| Example 41 | A | A | A | A | A | B |
| Example 42 | A | A | A | A | A | B |
| Example 43 | A | A | A | A | A | B |
| Example 44 | A | A | A | A | A | B |
| Example 45 | A | A | A | A | A | B |
| Example 46 | A | A | A | A | A | B |
| Example 47 | A | A | A | A | A | B |
| Example 48 | A | A | A | A | A | B |
| Example 49 | A | A | A | A | A | B |
| Example 50 | A | A | A | A | A | B |

TABLE 5

| | Compound X | | | | | | | Anticorrosion | |
|---|---|---|---|---|---|---|---|---|---|
| | | | | | Total | Compound Y | | agent | |
| | | Content | | Content | content | | Content | | Content |
| | | (% by | | (% by | (% by | | (% by | | (% by |
| | Type | mass | Type | mass) | mass) | Type | mass) | Type | mass) |
| Example | THEMAH | 4 | MDEA | 0.5 | 4.5 | — | — | Adenine | 0.2 |
| 51 | | | | | | | | | |
| Example | THEMAH | 4 | MDEA | 0.5 | 4.5 | — | — | Adenine | 0.2 |
| 52 | | | | | | | | | |
| Example | THEMAH | 4 | MDEA | 0.5 | 4.5 | — | — | Adenine | 0.2 |
| 53 | | | | | | | | | |
| Example | THEMAH | 4 | MDEA | 0.5 | 4.5 | — | — | Adenine | 0.2 |
| 54 | | | | | | | | | |
| Example | THEMAH | 4 | MDEA | 0.5 | 4.5 | — | — | Adenine | 0.2 |
| 55 | | | | | | | | | |
| Example | TMPN | 4 | PMDETA | 1.5 | 5.5 | AMP | 0.1 | Adenine | 0.2 |
| 56 | | | | | | | | | |
| Example | TMEN | 4 | PMDETA | 1.5 | 5.5 | AMP | 0.1 | Adenine | 0.2 |
| 57 | | | | | | | | | |
| Example | DMAMP | | — | — | 4 | AMP | 0.1 | Adenine | 0.2 |
| 58 | | | | | | | | | |
| Example | THEMAH | 4 | MDEA | 0.5 | 4.5 | — | — | Adenine | 0.2 |
| 59 | | | | | | | | | |
| Example | TEAH | 4 | MDEA | 0.5 | 4.5 | — | — | Adenine | 0.2 |
| 60 | | | | | | | | | |
| Example | DMAMP | 0.4 | — | — | 0.4 | AMP | 0.1 | Adenine | 0.2 |
| 61 | | | | | | | | | |
| Example | DMAMP | 1 | — | — | 1 | AMP | 0.1 | Adenine | 0.2 |
| 62 | | | | | | | | | |
| Example | DMAMP | 2 | — | — | 2 | AMP | 0.1 | Adenine | 0.2 |
| 63 | | | | | | | | | |
| Example | DMAMP | 4 | — | — | 4 | AMP | 0.1 | Adenine | 0.2 |
| 64 | | | | | | | | | |
| Example | DMAMP | 4 | — | — | 4 | AMP | 0.1 | Adenine | 0.2 |
| 65 | | | | | | | | | |
| Example | THEMAH | 4 | MDEA | 0.02 | 4.02 | — | — | Adenine | 0.2 |
| 66 | | | | | | | | | |
| Example | THEMAH | 4 | MDEA | 0.05 | 4.05 | — | — | Adenine | 0.2 |
| 67 | | | | | | | | | |
| Example | THEMAH | 4 | MDEA | 1 | 5 | — | — | Adenine | 0.2 |
| 68 | | | | | | | | | |
| Example | THEMAH | 4 | MDEA | 5 | 9 | — | — | Adenine | 0.2 |
| 69 | | | | | | | | | |
| Example | THEMAH | 4 | MDEA | 7.5 | 11.5 | — | — | Adenine | 0.2 |
| 70 | | | | | | | | | |
| Example | DMAMP | 4 | PMDETA | 1.5 | 5.5 | AMP | 0.1 | Adenosine | 0.004 |
| 71 | | | | | | | | | |
| Example | DMAMP | 4 | PMDETA | 1.5 | 5.5 | AMP | 0.1 | Adenosine | 0.005 |
| 72 | | | | | | | | | |
| Example | DMAMP | 4 | PMDETA | 1.5 | 5.5 | AMP | 0.1 | Adenosine | 0.2 |
| 73 | | | | | | | | | |
| Example | DMAMP | 4 | PMDETA | 1.5 | 5.5 | AMP | 0.1 | Adenosine | 1 |
| 74 | | | | | | | | | |
| Example | DMAMP | 4 | PMDETA | 1.5 | 5.5 | AMP | 0.1 | Adenosine | 2.5 |
| 75 | | | | | | | | | |
| Example | DMAMP | 4 | PMDETA | 1.5 | 5.5 | AMP | 0.1 | Adenosine | 8 |
| 76 | | | | | | | | | |

| | Organic solvent | | Organic acid | | | | |
|---|---|---|---|---|---|---|---|
| | | Content | | Content | pH | | |
| | | (% by | | (% by | adjusting | | |
| | Type | mass) | Type | mass) | agent | Water | pH |
| Example | EGME | 5 | SA | 0.1 | *1 | Remainder | 11.5 |
| 51 | | | | | | | |
| Example | EGBE | 5 | SA | 0.1 | *1 | Remainder | 11.5 |
| 52 | | | | | | | |
| Example | DEGBE | 5 | SA | 0.1 | *1 | Remainder | 11.5 |
| 53 | | | | | | | |
| Example | PC | 5 | SA | 0.1 | *1 | Remainder | 11.5 |
| 54 | | | | | | | |
| Example | CHN | 5 | SA | 0.1 | *1 | Remainder | 11.5 |
| 55 | | | | | | | |
| Example | MMB | 5 | SA | 0.1 | *1 | Remainder | 11.5 |
| 56 | | | | | | | |
| Example | MMB | 5 | SA | 0.1 | *1 | Remainder | 11.5 |
| 57 | | | | | | | |
| Example | MMB | 5 | SA | 0.1 | *1 | Remainder | 11.5 |
| 58 | | | | | | | |
| Example | MMB | 5 | SA | 0.1 | *1 | Remainder | 12.8 |
| 59 | | | | | | | |
| Example | MMB | 5 | SA | 0.1 | *1 | Remainder | 13.1 |
| 60 | | | | | | | |
| Example | MMB | 50 | — | — | *1 | Remainder | 10.5 |
| 61 | | | | | | | |
| Example | MMB | 20 | — | — | *1 | Remainder | 11.0 |
| 62 | | | | | | | |
| Example | MMB | 10 | — | — | *1 | Remainder | 11.5 |
| 63 | | | | | | | |
| Example | MMB | 4 | — | — | *1 | Remainder | 11.5 |
| 64 | | | | | | | |
| Example | MMB | 1 | — | — | *1 | Remainder | 11.5 |
| 65 | | | | | | | |
| Example | MMB | 5 | — | — | *1 | Remainder | 12.8 |
| 66 | | | | | | | |
| Example | MMB | 5 | — | — | *1 | Remainder | 12.8 |
| 67 | | | | | | | |
| Example | MMB | 5 | — | — | *1 | Remainder | 12.8 |
| 68 | | | | | | | |
| Example | MMB | 5 | — | — | *1 | Remainder | 12.8 |
| 69 | | | | | | | |
| Example | MMB | 5 | — | — | *1 | Remainder | 12.8 |
| 70 | | | | | | | |
| Example | MMB | 5 | SA | 0.1 | *1 | Remainder | 11.5 |
| 71 | | | | | | | |
| Example | MMB | 5 | SA | 0.1 | *1 | Remainder | 11.5 |
| 72 | | | | | | | |
| Example | MMB | 5 | SA | 0.1 | | Remainder | 11.5 |
| 73 | | | | | | | |
| Example | MMB | 5 | SA | 0.1 | *1 | Remainder | 11.5 |
| 74 | | | | | | | |
| Example | MMB | 5 | SA | 0.1 | *1 | Remainder | 11.5 |
| 75 | | | | | | | |
| Example | MMB | 5 | SA | 0.1 | *1 | Remainder | 11.5 |
| 76 | | | | | | | |

TABLE 6

| | | | | | Cu evaluation result | | | Co evaluation |
|---|---|---|---|---|---|---|---|---|
| | | | | | | | Suppression | result |
| | Compound | Compound | Organic | Anticorrosion | Removability | Removability | property of | Removability |
| | X/organic | Y/organic | acid/organic | agent/organic | of organic | of inorganic | surface | of organic |
| | solvent | solvent | solvent | solvent | residues | residues | roughness | residues |
| Example 51 | 0.9 | — | 0.02 | 0.04 | A | B | A | A |
| Example 52 | 0.9 | — | 0.02 | 0.04 | A | A | A | A |
| Example 53 | 0.9 | — | 0.02 | 0.04 | A | A | A | A |
| Example 54 | 0.9 | — | 0.02 | 0.04 | A | A | B | A |
| Example 55 | 0.9 | — | 0.02 | 0.04 | B | A | B | B |
| Example 56 | 1.1 | 0.02 | 0.02 | 0.04 | A | A | A | A |
| Example 57 | 1.1 | 0.02 | 0.02 | 0.04 | A | A | A | A |
| Example 58 | 0.8 | 0.02 | 0.02 | 0.04 | A | A | A | A |
| Example 59 | 0.9 | — | 0.02 | 0.04 | A | A | A | A |
| Example 60 | 0.9 | — | 0.02 | 0.04 | A | A | A | A |
| Example 61 | 0.008 | 0.002 | — | 0.004 | B | C | C | B |
| Example 62 | 0.05 | 0.005 | — | 0.01 | B | C | B | B |
| Example 63 | 0.2 | 0.01 | — | 0.02 | B | C | B | B |
| Example 64 | 1 | 0.025 | — | 0.05 | B | C | B | B |
| Example 65 | 4 | 0.1 | — | 0.2 | C | C | B | C |
| Example 66 | 0.80 | — | — | 0.04 | C | B | A | C |
| Example 67 | 0.81 | — | — | 0.04 | B | B | A | B |
| Example 68 | 1 | — | — | 0.04 | B | B | A | B |
| Example 69 | 1.8 | — | — | 0.04 | B | B | A | B |
| Example 70 | 2.3 | — | — | 0.04 | B | B | B | B |
| Example 71 | 1.1 | 0.02 | 0.02 | 0.0008 | A | A | B | A |
| Example 72 | 1.1 | 0.02 | 0.02 | 0.001 | A | A | A | A |
| Example 73 | 1.1 | 0.02 | 0.02 | 0.04 | A | A | A | A |
| Example 74 | 1.1 | 0.02 | 0.02 | 0.2 | A | A | A | A |
| Example 75 | 1.1 | 0.02 | 0.02 | 0.5 | A | A | A | A |
| Example 76 | 1.1 | 0.02 | 0.02 | 1.6 | B | A | A | B |

| | Co evaluation result | | W evaluation result | | |
|---|---|---|---|---|---|
| | | Suppression | | | Suppression |
| | Removability | property of | Removability | Removability | property of |
| | of inorganic | surface | of organic | of inorganic | surface |
| | residues | roughness | residues | residues | roughness |
| Example 51 | B | A | A | B | B |
| Example 52 | A | A | A | A | B |
| Example 53 | A | A | A | A | B |
| Example 54 | A | B | A | A | C |
| Example 55 | A | B | B | A | C |
| Example 56 | A | A | A | A | B |
| Example 57 | A | A | A | A | B |
| Example 58 | A | A | A | A | B |
| Example 59 | A | A | A | A | B |
| Example 60 | A | A | A | A | B |
| Example 61 | C | C | B | C | D |
| Example 62 | C | B | B | C | C |
| Example 63 | C | B | B | C | C |
| Example 64 | C | B | B | C | C |
| Example 65 | C | B | C | C | C |
| Example 66 | B | A | C | B | B |
| Example 67 | B | A | B | B | B |
| Example 68 | B | A | B | B | B |
| Example 69 | B | A | B | B | B |
| Example 70 | B | B | B | B | C |
| Example 71 | A | B | A | A | C |
| Example 72 | A | A | A | A | B |
| Example 73 | A | A | A | A | B |
| Example 74 | A | A | A | A | B |
| Example 75 | A | A | A | A | B |
| Example 76 | A | A | B | A | B |

TABLE 7

| | Compound X | | | | | | | Anticorrosion | |
|---|---|---|---|---|---|---|---|---|---|
| | | | | | Total | Compound Y | | agent | |
| | | Content | | Content | content | | Content | | Content |
| | | (% by | | (% by | (% by | | (% by | | (% by |
| | Type | mass) | Type | mass) | mass) | Type | mass) | Type | mass) |
| Example 77 | DMAMP | 4 | PMDETA | 1.5 | 5.5 | AMP | 0.1 | Adenine | 0.2 |
| Example 78 | DMAMP | 4 | PMDETA | 1.5 | 5.5 | AMP | 0.1 | Adenine | 0.2 |
| Example 79 | DMAMP | 4 | PMDETA | 1.5 | 5.5 | AMP | 0.1 | Adenine | 0.2 |
| Example 80 | DMAMP | 4 | PMDETA | 1.5 | 5.5 | AMP | 0.1 | Adenine | 0.2 |
| Example 81 | DMAMP | 4 | PMDETA | 1.5 | 5.5 | AMP | 0.1 | Adenine | 0.2 |
| Example 82 | DMAMP | 4 | PMDETA | 1.5 | 5.5 | AMP | 0.1 | Adenine | 0.2 |
| Comparative | DMAMP | 4 | — | — | 4 | — | — | Adenine | 0.2 |
| Example 1 | | | | | | | | | |
| Comparative | — | — | — | — | — | TEA | 4 | Adenine | 0.2 |
| Example 2 | | | | | | | | | |

| | Organic | | | | | | |
|---|---|---|---|---|---|---|---|
| | solvent | | Organic acid | | | | |
| | | Content | | Content | pH | | |
| | | (% by | | (% by | adjusting | | |
| | Type | mass) | Type | mass) | agent | Water | pH |
| Example 77 | MMB | 5 | SA | 0.01 | *1 | Remainder | 11.5 |
| Example 78 | MMB | 5 | SA | 0.05 | *1 | Remainder | 11.5 |
| Example 79 | MMB | 5 | SA | 0.5 | *1 | Remainder | 11.5 |
| Example 80 | MMB | 5 | SA | 3 | *1 | Remainder | 11.5 |
| Example 81 | MMB | 5 | SA | 5 | *1 | Remainder | 11.5 |
| Example 82 | MMB | 5 | SA | 7.5 | *1 | Remainder | 11.5 |
| Comparative | — | — | — | — | *1 | Remainder | 11.5 |
| Example 1 | | | | | | | |
| Comparative | MMB | 5 | — | — | *1 | Remainder | 9.0 |
| Example 2 | | | | | | | |

TABLE 8

| | | | | | Cu evaluation result | | |
|---|---|---|---|---|---|---|---|
| | | | | | | | Suppression |
| | Compound | Compound | | Anticorrosion | Removability | Removability | property of |
| | X/organic | Y/organic | Organic acid/organic | agent/organic | of organic | of inorganic | surface |
| | solvent | solvent | solvent | solvent | residues | residues | roughness |
| Example 77 | 1.1 | 0.02 | 0.002 | 0.04 | A | B | A |
| Example 78 | 1.1 | 0.02 | 0.01 | 0.04 | A | A | A |
| Example 79 | 1.1 | 0.02 | 0.1 | 0.04 | A | A | A |
| Example 80 | 1.1 | 0.02 | 0.6 | 0.04 | A | A | A |
| Example 81 | 1.1 | 0.02 | 1 | 0.04 | A | A | A |
| Example 82 | 1.1 | 0.02 | 1.5 | 0.04 | A | A | B |
| Comparative | — | — | — | — | E | D | D |
| Example 1 | | | | | | | |
| Comparative | — | — | — | — | D | D | E |
| Example 2 | | | | | | | |

| | Co evaluation result | | | W evaluation result | | |
|---|---|---|---|---|---|---|
| | | | Suppression | | | Suppression |
| | Removability | Removability | property of | Removability | Removability | property of |
| | of organic | of inorganic | surface | of organic | of inorganic | surface |
| | residues | residues | roughness | residues | residues | roughness |
| Example 77 | A | B | A | A | B | B |
| Example 78 | A | A | A | A | A | B |
| Example 79 | A | A | A | A | A | B |
| Example 80 | A | A | A | A | A | B |
| Example 81 | A | A | A | A | A | B |
| Example 82 | A | A | B | A | A | C |
| Comparative | E | D | D | E | D | E |
| Example 1 | | | | | | |
| Comparative | D | D | E | D | D | E |
| Example 2 | | | | | | |

As shown in the tables, it was confirmed that the desired effect was obtained with the cleaning composition according to the embodiment of the present invention.

In a case where the amine compound included at least one selected from the group consisting of the tertiary amine compound in which the pKa of the conjugate acid was 8.0 or more and the compound represented by Formula (B), it was confirmed that the effect of the present invention was more excellent (Examples 1 to 9).

In a case where the mass ratio of the content of the amine compound other than the compound X (compound Y) to the content of the organic solvent (content of compound Y/content of organic solvent) was 0.004 to 2, it was confirmed that the effect of the present invention was more excellent (Examples 10 to 16).

In a case where the tertiary amine compound in which the pKa of the conjugate acid was 8.0 or more included at least one selected from the group consisting of the tertiary amino alcohol in which the pKa of the conjugate acid was 8.0 or more and the compound represented by Formula (C), in which the pKa of the conjugate acid was 8.0 or more, it was confirmed that the effect of the present invention was more excellent (Examples 1, 3, and 19 to 22).

In a case where the anticorrosion agent included the purine compound, it was confirmed that the effect of the present invention was more excellent (Examples 24 and 27 to 33).

In a case where the organic acid was the dicarboxylic acid, it was confirmed that the effect of the present invention was more excellent (Examples 34 to 39).

In a case where, in the ternary diagram in which the contribution rate of the dispersion element, the contribution rate of the polarization element, and the contribution rate of the hydrogen bond element in the Hansen solubility parameter of the organic solvent were each represented by a vertex, the organic solvent was located in the region surrounded by the first point to the fourth point, it was confirmed that the effect of the present invention was more excellent (Examples 40 to 47 and 48 to 55). In addition, from the same comparison, in a case where the organic solvent included at least one selected from the group consisting of ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate, it was confirmed that the effect of the present invention was more excellent.

In a case where the mass ratio of the content of the compound X to the content of the organic solvent (content of compound X/content of organic solvent) was 0.01 to 1, it was confirmed that the effect of the present invention was more excellent (Examples 61 to 65).

In a case where the mass ratio of the content of the anticorrosion agent to the content of the organic solvent (content of anticorrosion agent/content of organic solvent) was 0.0009 to 1, it was confirmed that the effect of the present invention was more excellent (Examples 71 to 76).

In a case where the mass ratio of the content of the organic acid to the content of the organic solvent (content of organic acid/content of organic solvent) was 0.005 to 1.2, it was confirmed that the effect of the present invention was more excellent (Examples 77 to 82).

A cleaning composition of Example 83 was produced by the same procedure as in Example 41, except that, in the cleaning composition of Example 41, 3-methyl-2-oxazolidone with the same amount as EGBE was used instead of EGBE. As a result of the same evaluations as in the evaluation of Example 41 for the obtained cleaning composition of Example 83, the Cu evaluation results were removability of organic residues: “A”, removability of inorganic residues: “B”, and suppression property of surface roughness: “A”; the Co evaluation results were removability of organic residues: “A”, removability of inorganic residues: “B”, and suppression property of surface roughness: “A”; and the W evaluation results were removability of organic residues: “A”, removability of inorganic residues: “B”, and suppression property of surface roughness: “B”.

A cleaning composition of Example 84 was produced by the same procedure as in Example 41, except that, in the cleaning composition of Example 41, 1,3-dimethyl-2-imidazolidinone with the same amount as EGBE was used instead of EGBE. As a result of the same evaluations as in the evaluation of Example 41 for the obtained cleaning composition of Example 84, the Cu evaluation results were removability of organic residues: “B”, removability of inorganic residues: “A”, and suppression property of surface roughness: “A”; the Co evaluation results were removability of organic residues: “B”, removability of inorganic residues: “A”, and suppression property of surface roughness: “A”; and the W evaluation results were removability of organic residues: “B”, removability of inorganic residues: “A”, and suppression property of surface roughness: “B”.

Each of the cleaning compositions of each of Examples and Comparative Examples was further applied onto a polishing pad with respect to the above-described sample for removability evaluation, and each of the cleaning compositions was used as a buff cleaning liquid under the following conditions.
Table rotation speed: 80 rpm
Head rotation speed: 78 rpm
Polishing pressure: 60 hPa
Polishing pad: manufactured by Rodel-Nitta, FUJIBO800
Polishing liquid supply speed: 250 mL/min

Each obtained wafer was evaluated by the same procedures as the removability of organic residues and the removability of inorganic residues.

As a result, the same results as the evaluation results shown in the tables were obtained, and it was confirmed that the cleaning composition could also be used as a buff cleaning liquid.

What is claimed is:

1. A cleaning composition used for cleaning a substrate which has been subjected to a chemical mechanical polishing treatment, the cleaning composition comprising:
an amine compound;
an anticorrosion agent;
an organic solvent; and
water,
wherein the amine compound includes at least one compound X selected from the group consisting of a tertiary amine compound in which a pKa of a conjugate acid is 8.0 or more and a quaternary ammonium salt compound containing a quaternary ammonium cation having a total number of carbon atoms of 5 or more.

2. The cleaning composition according to claim 1,
wherein the amine compound includes at least one selected from the group consisting of the tertiary amine compound in which a pKa of a conjugate acid is 8.0 or more and a compound represented by Formula (B), 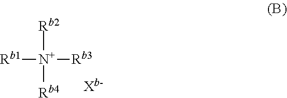
in Formula (B), R^{b1} to R^{b4} each independently represent an alkyl group which may have a substituent and may have —O—, X^{b-} represents an anion, here, a case where all of R^{b1} to R^{b4} represent the same group is excluded, and a total number of carbon atoms in R^{b1} to R^{b4} is 5 or more.

3. The cleaning composition according to claim 1,
wherein the tertiary amine compound in which a pKa of a conjugate acid is 8.0 or more includes at least one selected from the group consisting of a tertiary amino alcohol in which a pKa of a conjugate acid is 8.0 or more and a compound represented by Formula (C), in which a pKa of a conjugate acid is 8.0 or more, 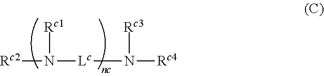
in Formula (C), R^{c1} to R^{c4} each independently represent an alkyl group, L^{c} represents an alkylene group, and nc represents an integer of 1 to 3.

4. The cleaning composition according to claim 1,
wherein the cleaning composition contains two or more kinds of the amine compounds.

5. The cleaning composition according to claim 1,
wherein the anticorrosion agent is a heterocyclic compound.

6. The cleaning composition according to claim 5,
wherein the anticorrosion agent includes at least one selected from the group consisting of a triazole compound, a tetrazole compound, an imidazole compound, a pyrazole compound, and a purine compound.

7. The cleaning composition according to claim 1,
wherein, in a ternary diagram in which a contribution rate of a dispersion element, a contribution rate of a polarization element, and a contribution rate of a hydrogen bond element in a Hansen solubility parameter of the organic solvent are each represented by a vertex, the organic solvent is located in a region surrounded by a first point to a fourth point,
first point: the contribution rate of the dispersion element is 30%, the contribution rate of the polarization element is 0%, and the contribution rate of the hydrogen bond element is 70%,
second point: the contribution rate of the dispersion element is 30%, the contribution rate of the polarization element is 70%, and the contribution rate of the hydrogen bond element is 0%,
third point: the contribution rate of the dispersion element is 60%, the contribution rate of the polarization element is 40%, and the contribution rate of the hydrogen bond element is 0%, and
fourth point: the contribution rate of the dispersion element is 60%, the contribution rate of the polarization element is 0%, and the contribution rate of the hydrogen bond element is 40%.

8. The cleaning composition according to claim 1,
wherein the organic solvent includes at least one selected from the group consisting of ethylene glycol alkyl ether including an alkyl ether having an alkyl group having 1 to 6 carbon atoms, diethylene glycol alkyl ether including an alkyl ether having an alkyl group having 1 to 6 carbon atoms, hexylene glycol, 3-methoxy-3-methyl-1-butanol, ethylene glycol monoethyl ether acetate, 2-methyl-2,4-pentanediol, dipropylene glycol butyl ether, 1-butoxy-2-propanol, 2-isobutoxyethanol, dimethyl sulfoxide, sulfolane, and propylene carbonate.

9. The cleaning composition according to claim 1,
wherein a mass ratio of a content of the compound X to a content of the organic solvent is 0.01 to 1.

10. The cleaning composition according to claim 1,
wherein a mass ratio of a content of the anticorrosion agent to a content of the organic solvent is 0.001 to 0.5.

11. The cleaning composition according to claim 1, further comprising:
an organic acid.

12. The cleaning composition according to claim 11,
wherein a mass ratio of a content of the organic acid to a content of the organic solvent is 0.01 to 1.

13. The cleaning composition according to claim 1,
wherein the cleaning composition is used for cleaning a semiconductor substrate having copper, cobalt, or tungsten, which has been subjected to a chemical mechanical polishing treatment.

14. A cleaning method of a semiconductor substrate, comprising:
a cleaning step of cleaning a semiconductor substrate which has been subjected to a chemical mechanical polishing treatment, using the cleaning composition according to claim 1.
